(19) United States
(12) Patent Application Publication
(10) Pub. No.: US 2025/0359374 A1
(43) Pub. Date: Nov. 20, 2025

(54) PIXEL SENSOR ARRAY AND METHODS OF FORMATION

(71) Applicant: Taiwan Semiconductor Manufacturing Company, Ltd., Hsinchu (TW)

(72) Inventors: Cheng-Yu HUANG, Hsinchu (TW); Chun-Hao CHUANG, Hsinchu City (TW); Wei-Chieh CHIANG, Yuanlin Township (TW); Shyh-Fann TING, Tainan City (TW)

(21) Appl. No.: 18/664,783

(22) Filed: May 15, 2024

(51) Int. Cl. H01L 27/146

(52) U.S. Cl. CPC H10F 39/807; H10F 39/014; H10F 39/182

(57) ABSTRACT

A metal insert is formed in a deep trench isolation (DTI) structure that laterally surrounds a photodiode of a pixel sensor, and the metal insert is formed in a manner in which a metal layer is formed and planarized to form the metal insert as opposed to etching the metal layer to form the metal insert. Recesses for diffusion structures are formed and then fully filled with a dielectric material as opposed to partially filling the recesses with a dielectric layer and then forming the metal layer on the dielectric layer. The diffusion structures have a substantially flat top surface on which the metal layer is then formed, which enables the metal layer to be planarized instead of etched to form the metal insert.

### BACKGROUND

Complementary metal oxide semiconductor (CMOS) image sensors utilize light-sensitive CMOS circuitry to convert light energy (e.g., photons) into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a pixel sensor described herein.

FIGS. 2A-2C are diagrams of examples of an image sensor device described herein.

FIGS. 3A-3E are diagrams of examples of pixel sensors that may be included in a pixel sensor array of an image sensor device described herein.

FIGS. 4A-4E are diagrams of examples of pixel sensors that may be included in a pixel sensor array of an image sensor device described herein.

FIGS. 5A-5E are diagrams of an example implementation of forming a circuitry die (or a portion thereof) described herein.

FIGS. 6A-6F are diagrams of an example implementation of forming a sensor die (or a portion thereof) described herein.

FIGS. 7A and 7B are diagrams of an example implementation of forming an image sensor device (or a portion thereof) described herein.

FIGS. 8A-8I are diagrams of an example implementation of forming a pixel sensor array of a sensor die (or a portion thereof) described herein.

FIGS. 9A-9I are diagrams of an example implementation of forming a pixel sensor array of a sensor die (or a portion thereof) described herein.

FIG. 10 is a flowchart of an example process associated with forming a pixel sensor array described herein.

FIG. 11 is a flowchart of an example process associated with forming a pixel sensor array described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, diffusion structures (also referred to as high absorption (HA) structures) may be included between a photodiode and a micro-lens of a pixel sensor. The diffusion structures distribute incident light across the photodiode to reduce the likelihood of optical saturation in an particular area in the photodiode, which may increase the quantum efficiency (QE) of the pixel sensor. However, the size and/or shape of the diffusion structures may be limited by the types of materials and surrounding structures that are included in the pixel sensor. For example, a metal insert may be formed in a deep trench isolation (DTI) structure that laterally surrounds the photodiode, and etching of a metal layer to form the metal insert may limit the width and/or the depth to which the diffusion structures may be formed. In particular, if recesses are formed for large diffusion structures, and the metal layer is formed in the recesses, a dielectric layer of the diffusion structures on which the metal layer is formed in the recesses may be damaged from etching the metal layer because of the variation in thickness of the metal layer that results from the size of the recesses. This may limit the capability for the diffusion structures to distribute particular wavelengths of light, which may result in low QE for the pixel sensor. Moreover, because the metal layer is etched to form the metal insert, some metals such as copper that have a high reflectivity are not suitable for use in the metal insert due to the impracticality of etching such metals.

In some implementations described herein, a metal insert is formed in a DTI structure that laterally surrounds a photodiode of a pixel sensor, and the metal insert is formed in a manner in which a metal layer is formed and planarized to form the metal insert as opposed to etching the metal layer to form the metal insert. Recesses for diffusion structures are formed and then fully filled with a dielectric material as opposed to partially filling the recesses with a dielectric layer and then forming the metal layer on the dielectric layer. In this way, the diffusion structures have a substantially flat top surface on which the metal layer is then formed, which enables the metal layer to be planarized instead of etched to form the metal insert.

Forming the metal insert after forming the diffusion structures prevents the materials of the metal insert from limiting the size and/or shape of the diffusion structures, which provides greater manufacturing flexibility when forming the diffusion structures. The greater flexibility in selecting the size and/or shape of the diffusion structures enables the diffusion structures to be formed to distribute incident light for specific optical wavelengths and/or for a broader range of optical bandwidths. This may increase the QE of the pixel sensor. Additionally and/or alternatively, forming the metal insert by planarization instead of etching enables metals that have a high reflectivity such as copper to be used for the metal insert. This may increase the reflectivity of the DTI structure, which may increase the optical isolation provided by the DTI structure. Moreover, fully filling the recesses with the dielectric material as opposed to partially filling the recesses with a dielectric layer and then fully filling the recesses after formation of the metal insert results in fewer semiconductor processing operations, which may reduce the cost, complexity, and/or time for manufacturing the pixel sensor.

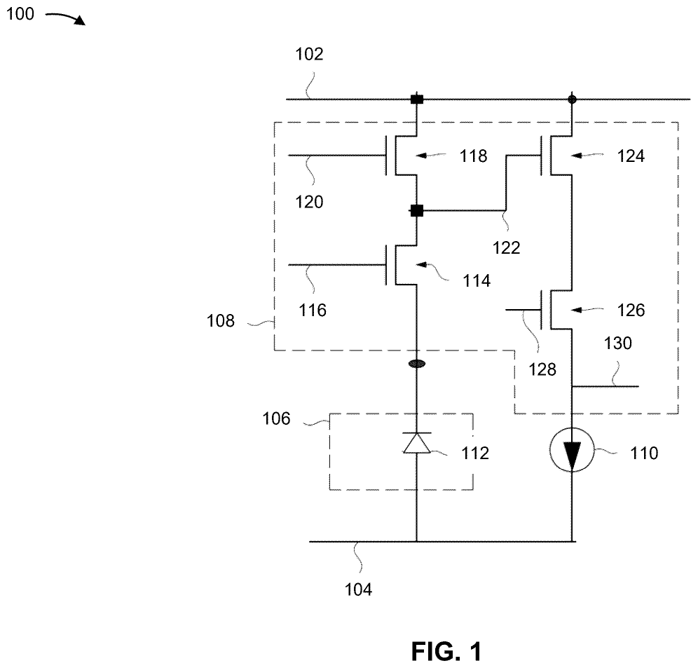

FIG. 1 is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor. The pixel sensor 100 may be electrically connected to a supply voltage (V_{dd}) 102 and an electrical ground 104.

The pixel sensor 100 includes a sensing region 106 that may be configured to sense and/or accumulate incident light (e.g., light directed toward the pixel sensor 100). The pixel sensor 100 also includes a control circuitry region 108. The control circuitry region 108 is electrically connected with the sensing region 106 and is configured to receive a photocurrent 110 that is generated by the sensing region 106. Moreover, the control circuitry region 108 is configured to transfer the photocurrent 110 from the sensing region 106 to downstream circuits such as amplifiers or analog-to-digital (AD) converters, among other examples.

The sensing region 106 includes a photodiode 112. The photodiode 112 may absorb and accumulate photons of the incident light, and may generate the photocurrent 110 based on absorbed photons. The magnitude of the photocurrent 110 is based on the amount of light collected in the photodiode 112. Thus, the accumulation of photons in the photodiode 112 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 112 is electrically connected with a source of a transfer gate 114 in the control circuitry region 108. The transfer gate 114 is configured to control the transfer of the photocurrent 110 from the photodiode 112. The photocurrent 110 is provided from the source of the transfer gate 114 to a drain of the transfer gate 114 based on selectively switching a gate of the transfer gate 114. The gate of the transfer gate 114 may be selectively switched by applying a transfer voltage (Vₜₓ) 116 to the transfer gate 114. In some implementations, the transfer voltage 116 being applied to the transfer gate 114 causes a conductive channel to form between the source and the drain of the transfer gate 114, which enables the photocurrent 110 to traverse along the conductive channel from the source to the drain. In some implementations, the transfer voltage 116 being removed from the transfer gate 114 (or the absence of the transfer voltage 116) causes the conductive channel to be removed such that the photocurrent 110 cannot pass from the source to the drain.

The control circuitry region 108 further includes a reset gate 118. The reset gate 118 is electrically connected to the supply voltage 102. The reset gate 118 may be controlled by a reset voltage (Vᵣₛₜ) 120. The transfer gate 114 and the reset gate 118 may be electrically coupled with a floating diffusion node 122. The reset voltage 120 may be applied to the reset gate 118 to pull the drain of the transfer gate 114 to a high voltage (e.g., to the supply voltage 102) to “reset” the floating diffusion node 122 (e.g., by draining any residual charge in the floating diffusion node 122) prior to activation of the transfer gate 114 to transfer the photocurrent 110 from the photodiode 112 to the floating diffusion node 122.

The photocurrent 110 may be used to apply a floating diffusion voltage (V_{fd}) to a source follower gate 124 of the control circuitry region 108. This permits the photocurrent 110 to be observed without removing or discharging the photocurrent 110 from the floating diffusion node 122. The reset gate 118 may instead be used to remove or discharge the photocurrent 110 from the floating diffusion node 122.

The source follower gate 124 functions as a high impedance amplifier for the pixel sensor 100. The source follower gate 124 provides a voltage to current conversion of the floating diffusion voltage. The output of the source follower gate 124 is electrically connected with a row select gate 126, which is configured to control the flow of the photocurrent 110 to external circuitry. The row select gate 126 is controlled by selectively applying a select voltage (V_{di}) 128 to the gate of the row select gate 126. This permits the photocurrent 110 to flow to an output 130 of the pixel sensor 100.

As indicated above, FIG. 1 is provided as an example. Other examples may differ from what is described with regard to FIG. 1.

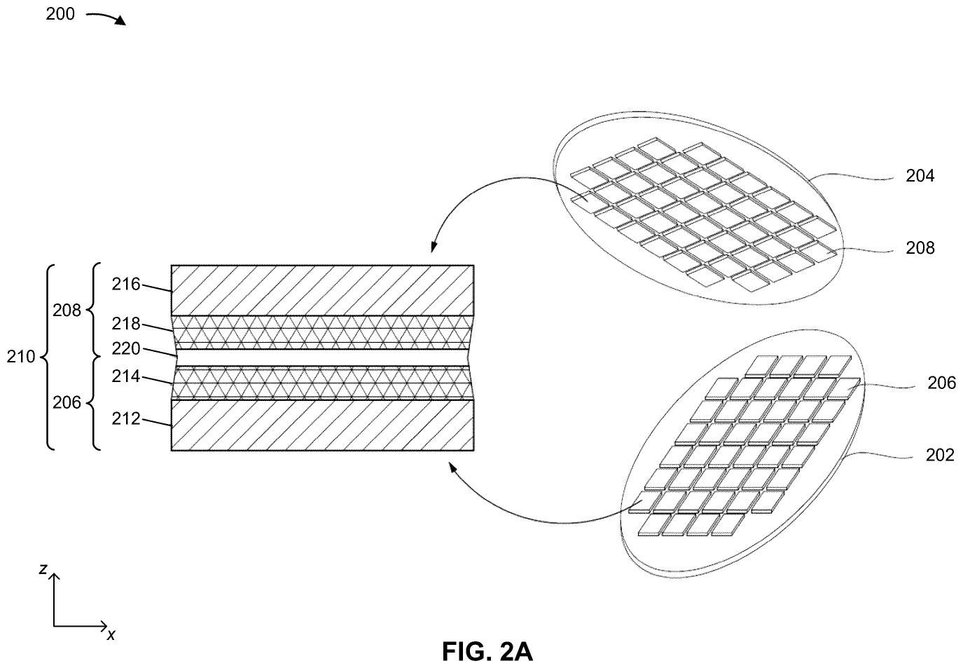

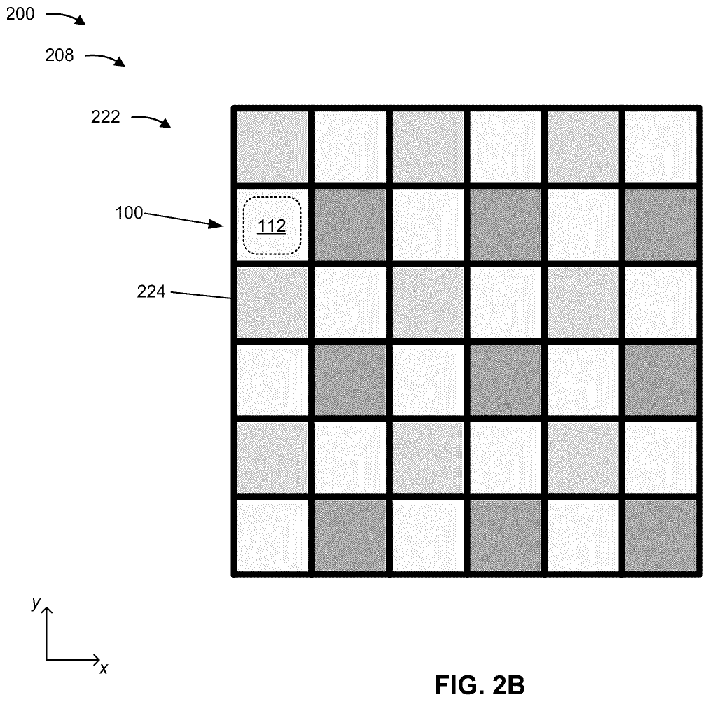

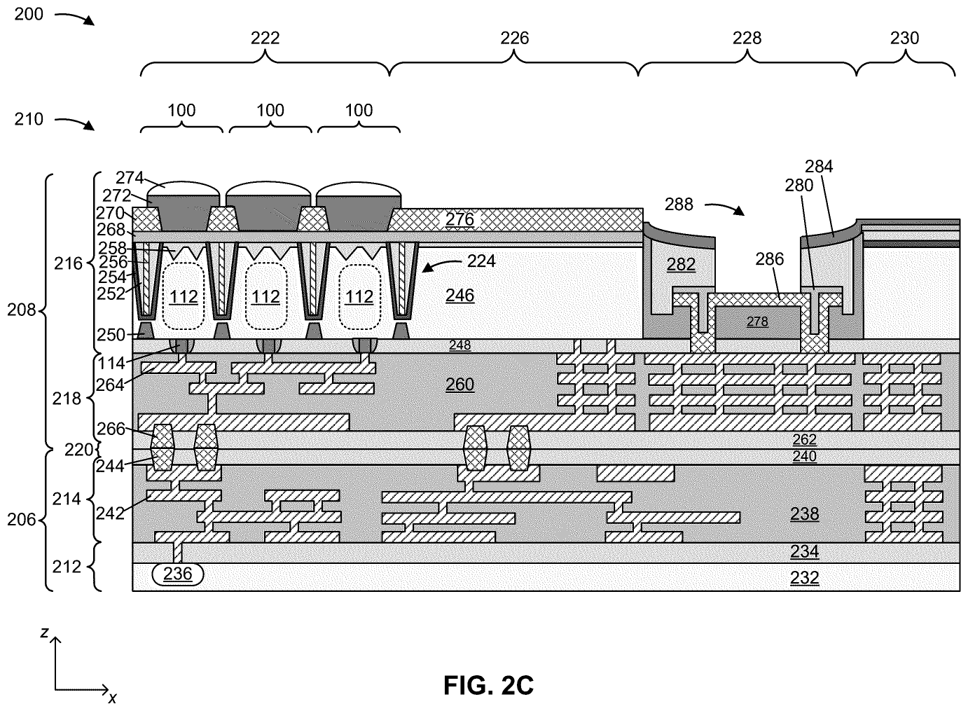

FIGS. 2A-2C are diagrams of examples 200 of an image sensor device described herein. As shown in FIG. 2A, an image sensor device may be formed by bonding a circuitry wafer 202 and a sensor wafer 204. For example, a bonding tool may be used to perform a bonding operation to bond the circuitry wafer 202 and the sensor wafer 204 using a metal-to-metal bonding technique, a dielectric-to-dielectric bonding technique, and/or another bonding technique. In the bonding operation, circuitry dies 206 on the circuitry wafer 202 are bonded with associated sensor dies 208 on the sensor wafer 204 to image sensor devices 210. The image sensor devices 210 are then diced and packaged. Other processing steps may be performed to form the image sensor devices 210.

Each image sensor device 210 includes a circuitry die 206 and a sensor die 208. The circuitry die 206 and the sensor die 208 may be stacked or vertically arranged in the image sensor device 210. The sensor die 208 includes a pixel sensor array that includes a plurality of pixel sensors 100, or portions of a plurality of pixel sensors 100. In particular, the pixel sensor array includes at least the sensing regions 106 (and thus, the photodiodes 112) of the pixel sensors 100. Accordingly, the sensor die 208 primarily is configured to sense photons of incident light and convert the photons to a photocurrent 110.

The circuitry die 206 includes circuitry that is configured to measure, manipulate, and/or otherwise use the photocurrent 110. Moreover, the circuitry die 206 includes at least a subset of the transistors of the control circuitry regions 108 of the pixel sensors 100. For example, the circuitry die 206 may include the row select gates 126 of the pixel sensors 100, the source follower gates 124 of the pixel sensor, and/or a combination thereof. This provides increased area on the sensor die 208 for the photodiodes 112, which enables the size of the photodiodes 112 to be increased to increase the sensitivity and/or overall performance of the light sensing performance of the pixel sensor, and/or enables the size of the pixel sensors 100 to be decreased while maintaining the same size for the photodiodes 112.

As further shown in FIG. 2A, the circuitry die 206 may include a device layer 212 and an interconnect layer 214. The device layer 212 may include the devices (e.g., transistors) of the circuitry die 206, and the interconnect layer 214 may include interconnects that enable signals and/or power to be provided to and/or from the devices in the device layer 212. The sensor die 208 may also include a device layer 216 and an interconnect layer 218. The device layer 216 may include portions of the pixel sensors 100, including the photodiodes 112, the transfer gates 114, and the floating diffusion nodes 122, among other examples. The interconnect layer 218 may include interconnects that enable signals and/or power to be provided to and/or from the device layer 216.

The circuitry die 206 and the sensor die 208 may be bonded at a bonding interface 220, which may be included between the interconnect layers 214 and 218, and/or may be included in a portion of the interconnect layers 214 and/or 218. The bonding interface 220 may include bonding pads, bonding vias, bonding dielectric layers, and/or other bonding structures.

FIG. 2B is a top-down view of an example pixel sensor array 222 included on a sensor die 208. The pixel sensor array 222 may be included on a sensor die 208 of an image sensor device 210. As shown in FIG. 2B, the pixel sensor array 222 may include a plurality of pixel sensors 100 (or portions of the plurality of plurality of pixel sensors 100). For example, the pixel sensor array 222 may include the photodiodes 112 of the pixel sensors 100. As further shown in FIG. 2B, the pixel sensors 100 may be arranged in a grid. In some implementations, the pixel sensors 100 are square-shaped (as shown in the example in FIG. 2B). In some implementations, the pixel sensors 100 include other shapes such as rectangle shapes, circle shapes, octagon shapes, diamond shapes, and/or other shapes.

In some implementations, the size of the pixel sensors 100 (e.g., the width or the diameter) of the pixel sensors 100 is approximately 1 micron. In some implementations, the size of the pixel sensors 100 (e.g., the width or the diameter) of the pixel sensors 100 is less than approximately 1 micron. For example, a width of one or more of the pixel sensors 100 may be included in a range of approximately 0.6 microns to approximately 0.7 microns. In these examples, the pixel sensors 100 may be referred to as sub-micron pixel sensors. Sub-micron pixel sensors may decrease the pixel sensor pitch (e.g., the distance between adjacent pixel sensors) in the pixel sensor array 222, which may enable increased pixel sensor density in the pixel sensor array 222 (which can increase the performance of the pixel sensor array 222). However, other values for the range of the size of the pixel sensors 100 are within the scope of the present disclosure.

Each pixel sensor 100 may be configured to sense a particular wavelength range of incident light associated with a particular color component of the incident light. For example, a pixel sensor 100 may be configured to sense a wavelength range associated with a red component of incident light, and may therefore be referred to as a red pixel sensor. As another example, a pixel sensor 100 may be configured to sense a wavelength range associated with a blue component of incident light, and may therefore be referred to as a blue pixel sensor. As another example, a pixel sensor 100 may be configured to sense a wavelength range associated with a green component of incident light, and may therefore be referred to as a green pixel sensor. In some implementations, a plurality of pixel sensors 100 are configured to sense a wavelength range associated with a near infrared (NIR) component of incident light, and may therefore be referred to as NIR pixel sensors. The NIR pixel sensors may be included in the pixel sensor array 222 to improve low-light performance of the image sensor device 210 and/or to enable night-vision functionality to be realized for the image sensor device 210.

As further shown in FIG. 2B, the pixel sensors 100 may be electrically and optically isolated by a DTI structure 224 included in the pixel sensor array 222. The DTI structure 224 may include a plurality of interconnected and intersecting trenches in a substrate that are filled with one or more types of materials, such as a dielectric material, a metal material, and/or another type of material. The trenches of the DTI structure 224 may be included around the perimeters of the pixel sensors 100 such that the DTI structure 224 forms an isolation grid that surrounds the photodiodes 112 of the pixel sensors 100, as shown in FIG. 2B.

FIG. 2C illustrates a cross-section view of an image sensor device 210. As shown in FIG. 2C, a circuitry die 206 and a sensor die 208 may be bonded at a bonding interface 220 such that the circuitry die 206 and the sensor die 208 are stacked or vertically arranged in a z-direction in the image sensor device 210. As further shown in FIG. 2C, the image sensor device 210 includes the pixel sensor array 222 (e.g., including the pixel sensors 100), a black level correction (BLC) region 226 adjacent to (e.g., horizontally adjacent to) the pixel sensor array 222, a bonding pad region 228 adjacent to (e.g., horizontally adjacent to) the BLC region 226, and a seal ring region 230 adjacent to (e.g., horizontally adjacent to) the bonding pad region 228, among other examples.

As further shown in FIG. 2C, the image sensor device 210 includes a plurality of layers, such as the device layer 212 and the interconnect layer 214 of the circuitry die 206, and the device layer 216 and the interconnect layer 218 of the sensor die 208. The device layer 212 of the circuitry die 206 includes a substrate 232 and a dielectric layer 234 above the substrate 232. The substrate 232 may include silicon (Si) (e.g., a silicon substrate), a material including silicon, a III-V compound semiconductor material such as gallium arsenide (GaAs), a silicon on insulator (SOI), or another type of semiconductor material. The substrate 232 may include a semiconductor layer such as a silicon layer. The dielectric layer 234 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

Devices 236 may be included in and/or on the substrate 232 of the device layer 212. The devices 236 may include one or more application-specific integrated circuit (ASIC) devices, one or more system-on-chip (SOC) devices, one or more transistors, and/or one or more other components configured to measure the magnitude of a photocurrent 110 generated by the pixel sensors 100 to determine light intensity of incident light and/or to generate images and/or video (e.g., digital images, digital video).

The interconnect layer 214 of the circuitry die 206 may include a dielectric layer 238, a bonding layer 240, a plurality of interconnect structures 242 in the dielectric layer 238, and a plurality of bonding structures 244 in the bonding layer 240. The dielectric layer 238 may include one or more interlayer dielectric (ILD) layers, one or more intermetal dielectric (IMD) layers, and/or one or more etch stop layers (ESLs), among other examples. The dielectric layer 238 and the bonding layer 240 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 242 may each include conductive lines, trenches, vias, interconnects, metallization layers, and/or other types of electrically conductive structures that electrically connect the devices 236 to one or more other regions of the circuitry die 206 and/or to one or more regions of the sensor die 208, among other examples. The bonding structures 244 may each include bonding pads, bonding vias, and/or other types of bonding structures. The interconnect structures 242 and the bonding structures 244 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

The device layer 216 of the sensor die 208 includes a substrate 246 and a dielectric layer 248 below the substrate 246. The substrate 246 may include silicon (Si) (e.g., a silicon substrate), a silicon layer or another type of semiconductor layer, a material including silicon, a III-V compound semiconductor material such as gallium arsenide (GaAs), an SOI, or another type of semiconductor material. The dielectric layer 248 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The photodiodes 112 of the pixel sensors 100 are included in the substrate 246 of the sensor die 208. The photodiodes 112 may each include one or more doped regions of substrate 246. The substrate 246 may be doped with a plurality of types of ions to form a p-n junction or a PIN junction (e.g., a junction between a p-type portion, an intrinsic (or undoped) type portion, and an n-type portion) corresponding to a photodiode 112. For example, the substrate 246 may be doped with an n-type dopant to form a first portion (e.g., an n-type portion) of a photodiode 112 and a p-type dopant to form a second portion (e.g., a p-type portion) of the photodiode 112. A photodiode 112 may be configured to absorb photons of incident light. The absorption of photons causes the photodiode 112 to accumulate a charge (a photocurrent 110) due to the photoelectric effect. Here, photons bombard the photodiode 112, which causes emission of electrons of the photodiode 112. The emission of electrons causes the formation of electron-hole pairs, where the electrons migrate toward the cathode of the photodiode 112 and the holes migrate toward the anode, which produces the photocurrent 110.

The photodiodes 112 may be electrically isolated and/or optically isolated from one another by one or more isolation structures in the substrate 246. Shallow trench isolation (STI) structures 250 extend into the substrate 246 from a bottom side of the substrate 246 (referred to as the front side of the substrate 246), and the DTI structure 224 extends into the substrate 246 from a top side of the substrate 246 (referred to as the back side of the substrate 246) over the STI structures 250. The combination of the STI structures 250 and the DTI structure 224 in the substrate 246 laterally surround the pixel sensors 100 in the substrate 246 and provide the electrically isolation and/or optically isolation for the pixel sensors 100 in the substrate 246.

The DTI structure 224 may include elongated structures that include a dielectric layer 252 and a dielectric liner 254 between the dielectric layer 252 and the substrate 246. The dielectric liner 254 may be a conformal liner that included on, and conforms to the profile of, sidewalls and a bottom surface of the DTI structure 224. Th dielectric liner may be included as an antireflective coating (ARC), to passivate the substrate 246 near the DTI structure 224, and/or to further facilitate electrical and/or optical isolation of the pixel sensors 100. The DTI structure 224 further includes an elongated metal insert 256 that extends into the dielectric layer 252 and provides enhanced reflectivity for the DTI structure 224. The metal insert 256 increases the reflection of photons of incident light off of the DTI structure 224 and towards the photodiodes 112 of the pixel sensors 100 as opposed to the photons being absorbed in the DTI structure 224, which may increase the QE of the pixel sensors 100. Additionally and/or alternatively, the metal insert 256 may be electrically biased to increase positive charge density (e.g., hole density) around the photodiodes 112.

The STI structures 250 may include one or more dielectric materials, such as a silicon oxide (SiOₓ), a silicon nitride (SiₓN_{y}), and/or a silicon oxynitride (SiON), among other examples. The dielectric layer 252 of the DTI structure 224 may include a silicon oxide (SiOₓ such as SiO₂), phosphosilicate glass (PSG), borophosphosilicate glass (BPSG), fluorinated silica glass (FSG), another low dielectric constant (low-k) dielectric material having a dielectric constant of approximately 3.9 or less, and/or another dielectric material. In some implementations, the dielectric liner 254 may include a high dielectric constant (high-k) dielectric material such as a silicon nitride (SiₓN_{y} such as Si₃N₄), a hafnium oxide (HfOₓ such as HfO₂), an aluminum oxide (AlₓO_{y} such as Al₃O₄), and/or another high-k dielectric material having a dielectric constant greater than approximately 3.9.

The metal insert 256 includes one or more metal materials and/or one or more metal-containing materials having a high optical reflectivity. Examples of such materials include copper (Cu), tungsten (W), titanium (Ti), aluminum (Al), gold (Au), silver (Ag), platinum (Pt), and/or zinc (Sn), among other examples. In some implementations, the metal that is used for the metal insert 256 may be based on the operational wavelength or operational wavelength range of incident light for the pixel sensor array 222. For example, if the pixel sensor array 222 is to be used in a low-light application in the pixel sensors 100 are to detect incident light in an infrared or NIR wavelength range, copper, gold, or another metal having high reflectivity for NIR light may be used. As another example, if the pixel sensors 100 are to detect incident light in a visible light wavelength range, silver, aluminum, or another metal having high reflectivity for visible light may be used.

As further shown in FIG. 2C, diffusion structures 258 may be included above the photodiodes 112 of the pixel sensors 100. The diffusion structures 258 are included to diffuse or scatter photons of incident light into the substrate 246, causing the photons to traverse a longer path to the photodiodes 112. The longer path of travel of the photons provides more opportunities for the photons to be absorbed in the photodiodes 112, thereby increasing the likelihood that the photons will be absorbed. This increases the QE of the pixel sensors 100.

The diffusion structures 258 may be located within the perimeter of the DTI structure 224 in a top view of the pixel sensor array 222 and between opposing sections of the DTI structure 224 on opposing sides of a photodiode 112 in cross-section view of the pixel sensor array 222. The diffusion structures 258 include dielectric material that is included in recesses in the substrate 246 above the photodiodes 112. Thus, the diffusion structures 258 extend into the substrate 246. The bottom surfaces of the diffusion structures 258 may have a V-shaped cross-sectional profile because of the recesses in the substrate 246 having angled sidewalls. Alternatively, the bottom surfaces of the diffusion structures 258 may have rounded sidewalls. The sidewalls of the recesses in which the diffusion structures 258 are formed cause the path traveled by photons into the substrate 246 to be modified through diffraction at the interface between the diffusion structures 258 and the substrate 246. The top surfaces of the diffusion structures 258 may be substantially flat. The dielectric material of the diffusion structures 258 may be merged across adjacent diffusion structures 258.

The DTI structure 224 and the diffusion structures 258 are included in the backside of the substrate 246. On the front side of the substrate 246, transfer gates 114 of the pixel sensors 100 are included, and the dielectric layer 248 is included over the transfer gates 114. The transfer gates 114 are electrically connected to the interconnect layer 218, which enables inputs (e.g., gate voltages) to be provided to the transfer gates 114 to control the flow of photocurrents 110 from the photodiodes 112 to floating diffusion nodes 122 (not shown) of pixel sensors 100.

The interconnect layer 218 may include a dielectric layer 260, a bonding layer 262, a plurality of interconnect structures 264 in the dielectric layer 260, and a plurality of bonding structures 266 in the bonding layer 262. The dielectric layer 260 may include one or more ILD layers, one or more IMD layers, and/or one or more ESLs, among other examples. The dielectric layer 260 and the bonding layer 262 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 264 may each include conductive lines, trenches, vias, interconnects, metallization layers, and/or other types of electrically conductive structures that electrically connect the transfer gates 114 to one or more other regions of the sensor die 208 and/or to one or more regions of the circuitry die 206, among other examples. The bonding structures 266 may each include bonding pads, bonding vias, and/or other types of bonding structures. The interconnect structures 264 and the bonding structures 266 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

At the bonding interface 220, the bonding layers 240 and 262 may be bonded together (e.g., in a dielectric-to-dielectric bond), and the bonding structures 244 and 266 may be bonded together (e.g., in a metal-to-metal bond). Signals and/or power may be provided between the circuitry die 206 and the sensor die 208 through the bonding structures 244 and 266.

Above the top side of the substrate 246, a passivation layer 268 may be included above the DTI structure 224 and above the diffusion structures 258, and a metal grid structure 270 may be included above the passivation layer 268. The passivation layer 268 may include an oxide material such as a silicon oxide (SiOₓ). Additionally and/or alternatively, a silicon nitride (SiNx), a silicon carbide (SiCx), or a mixture thereof, such as a silicon carbon nitride (SiCN), a silicon oxynitride (SiON), or another dielectric material is used for the passivation layer 268.

Sections of the metal grid structure 270 may be located over the DTI structure 224 and may be formed around the perimeter of the photodiodes 112 of the pixel sensors 100. Openings in the metal grid structure 270 are included above the photodiodes 112 to enable incident light to pass through the metal grid structure 270 and to the photodiodes 112. The metal grid structure 270 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

Color filter regions 272 of the pixel sensors 100 be included in the openings in the metal grid structure 270. The color filter regions 272 may be included above the photodiodes 112 of the pixel sensors 100. The color filter regions 272 may be included above the photodiodes 112. Each color filter region 272 may be configured to filter incident light to allow a particular wavelength of the incident light to pass to a photodiode 112. For example, a color filter region 272 may filter incident light to allow red light to pass through the color filter region 272 to an associated photodiode 112. As another example, a color filter region 272 may filter incident light to allow green light to pass through the color filter region 272 to an associated photodiode 112. As another example, a color filter region 272 may filter incident light to allow blue light to pass through the color filter region 272 to an associated photodiode 112. In some implementations, a color filter region 272 may be non-discriminating or non-filtering, which may define a white pixel sensor. A non-discriminating or non-filtering color filter region 272 may include a material that permits all wavelengths of light to pass into the associated photodiode 112 (e.g., for purposes of determining overall brightness to increase light sensitivity for the image sensor). In some implementations, a color filter region 272 may be an NIR bandpass color filter region 272, which may define an NIR pixel sensor. An NIR bandpass color filter region 272 may include a material that permits the portion of incident light in an NIR wavelength range to pass to an associated photodiode 112 while blocking visible light from passing.

Micro-lenses 274 may be included over and/or on the color filter regions 272. The micro-lenses 274 may include a respective micro-lens for each of the pixel sensors 100. A micro-lens may be formed to focus incident light toward a photodiode 112 of an associated pixel sensor 100.

As further shown in FIG. 2C, a metal layer 276 may be included above the substrate 246 in the BLC region 226 of the substrate 246. The metal layer 276 may be included as a light-blocking layer to prevent incident light from entering the portion of substrate 246 in the BLC region 226. The portion of substrate 246 in the BLC region 226 is thus a sensing region that is kept “dark” so that dark current measurements may be performed in the BLC region 226. A dark current measurement may be performed to measure the amount of charge (dark current) in the substrate 246 that is generated from sources other than incident light (e.g., from thermal energy in the substrate 246) so that the dark current measurement may be used for black level correction (or black level calibration) for the pixel sensor array 222.

As further shown in FIG. 2C, the bonding pad region 228 may include a plurality of dielectric layers 278, 280, 282, and 284 that electrically isolate a bonding pad structure 286. The bonding pad structure 286 is electrically coupled and/or physically coupled with one or more of the interconnect structures 264 in the interconnect layer 218 of the sensor die 208. A bonding pad opening 288 is included above the bonding pad structure 286 to enable an external electrical connection to be formed to the bonding pad structure 286.

The plurality of dielectric layers 278, 280, 282, and 284 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples. The bonding pad structure 286 may include a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

The seal ring region 230 includes a plurality of stacked interconnect structures 242 in the interconnect layer 214 and a plurality of stacked interconnect structures 264 in the interconnect layer 218 to seal the structures and layers of the image sensor device 210 to prevent ingress of humidity and other contaminants, as well as to provide structural rigidity to the image sensor device 210.

As indicated above, FIGS. 2A-2C are provided as examples. Other examples may differ from what is described with regard to FIGS. 2A-2C.

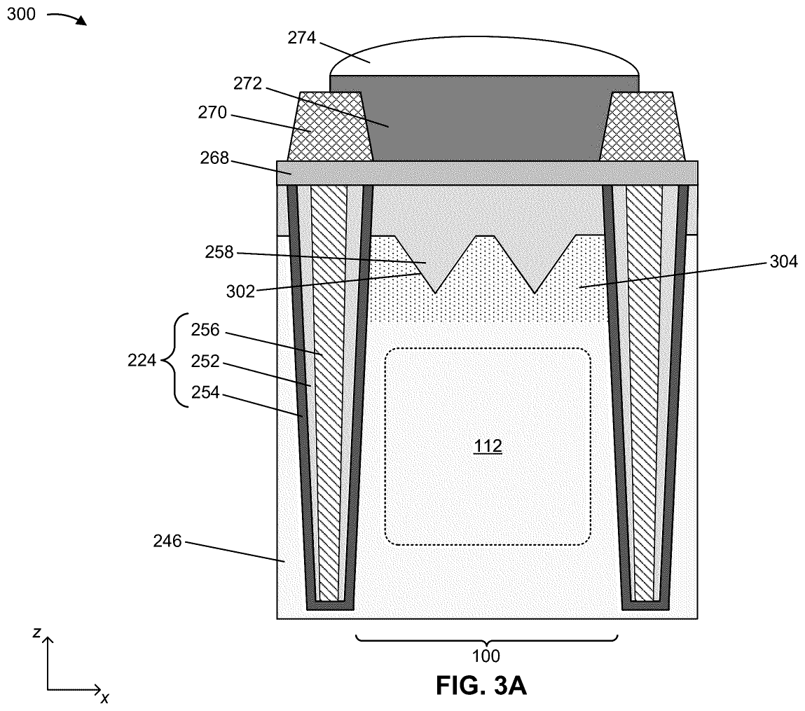

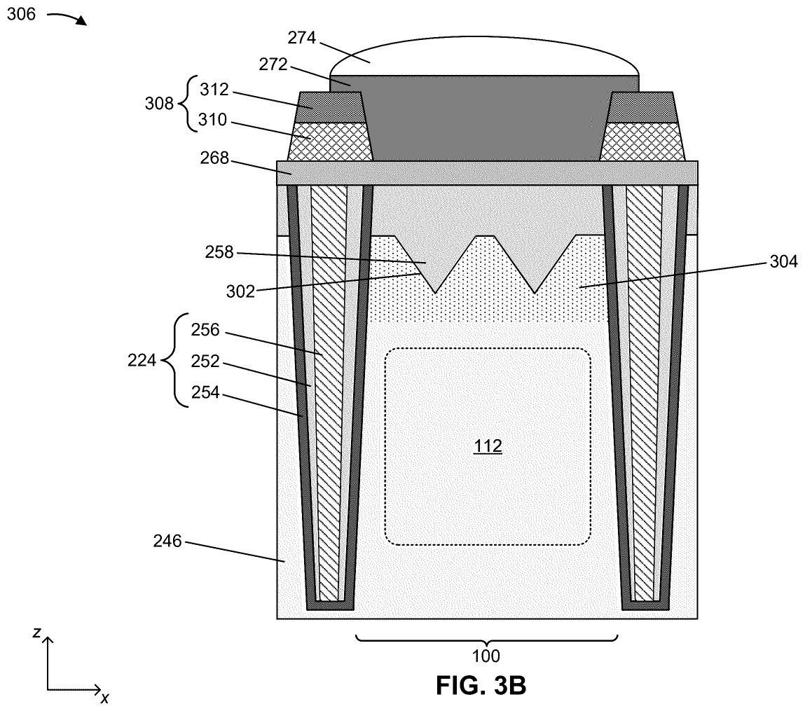

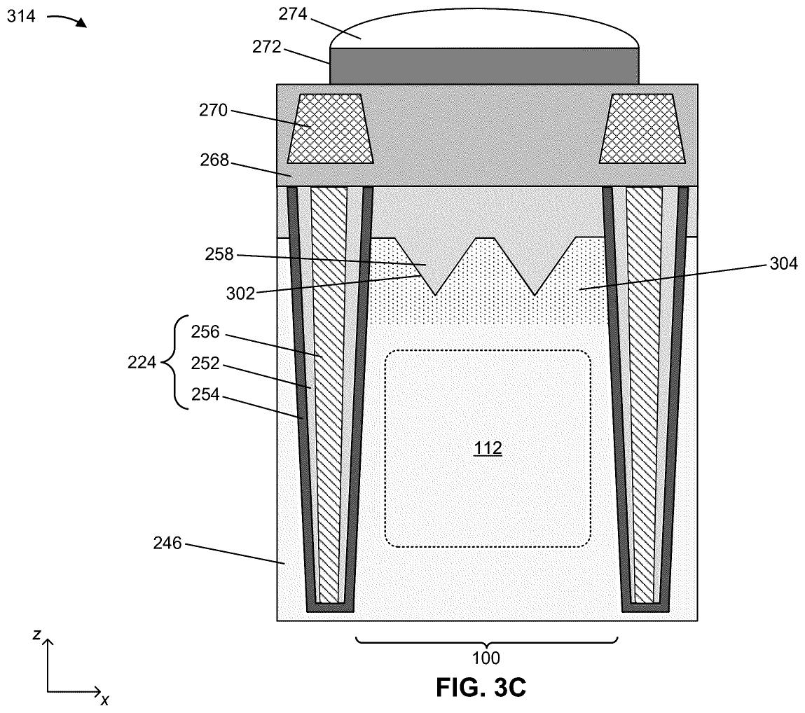

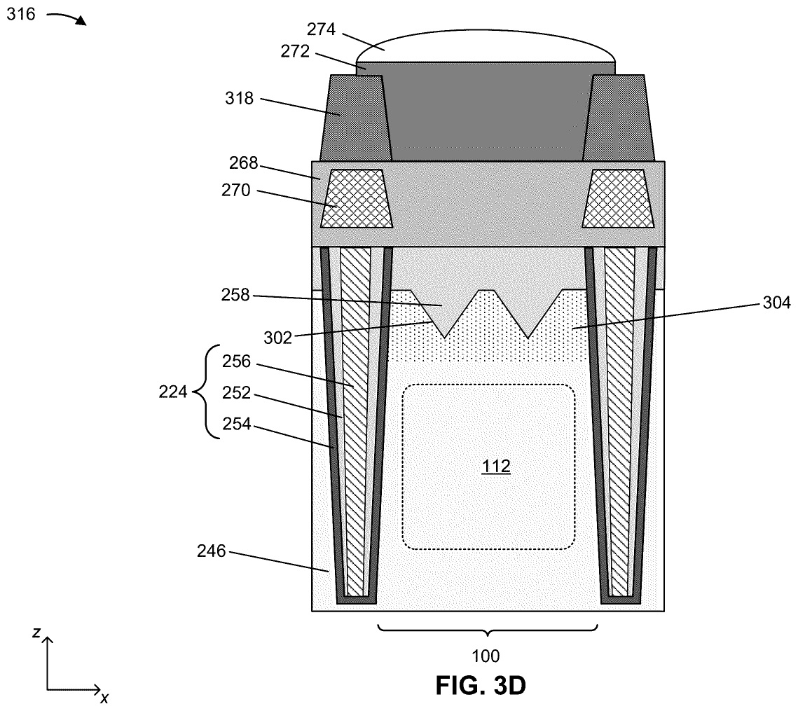

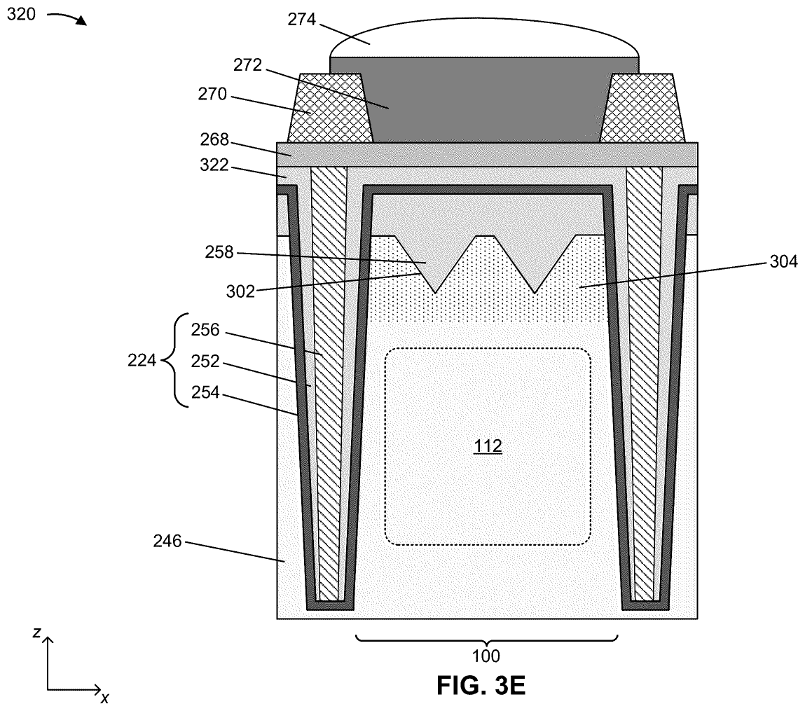

FIGS. 3A-3E are diagrams of examples of pixel sensors 100 that may be included in a pixel sensor array 222 of an image sensor device 210 described herein. As shown in FIG. 3A, an example 300 of a pixel sensor 100 includes a photodiode 112 in the substrate 246 of the sensor die 208. A color filter region 272 and a micro-lens 274 of the pixel sensor 100 are included above the photodiode 112.

As further shown in FIG. 3A, the DTI structure 224 is included in the substrate 246 and laterally surrounds the photodiode 112 in the substrate 246. Above the photodiode 112 are one or more diffusion structures 258 between the substrate 246 and a passivation layer 268. The diffusion structures 258 are included between sections of the DTI structure 224. In a top view of the pixel sensor 100, the diffusion structures 258 are included within an inner perimeter of the portion of the DTI structure 224 around the photodiode 112.

The DTI structure 224 includes the dielectric layer 252, the dielectric liner 254 (e.g., a conformal liner) between the dielectric layer 252 and the substrate 246, and a metal insert (e.g., an elongated metal insert in the cross-section view in FIG. 3A) in the dielectric layer 252. The DTI structure 224, including the dielectric layer 252, the dielectric liner 254, and the metal insert 256 may each extend above the backside surface of the substrate 246.

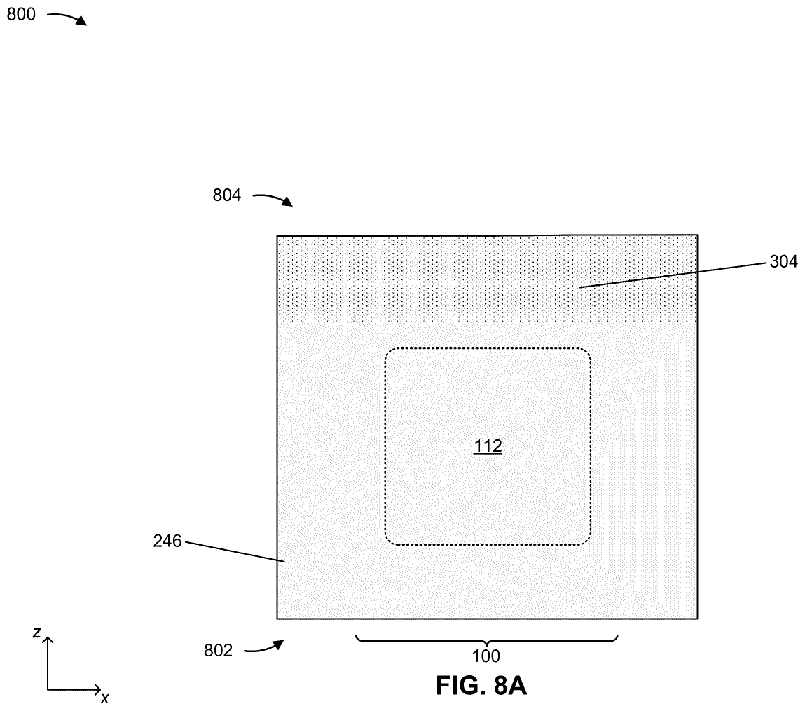

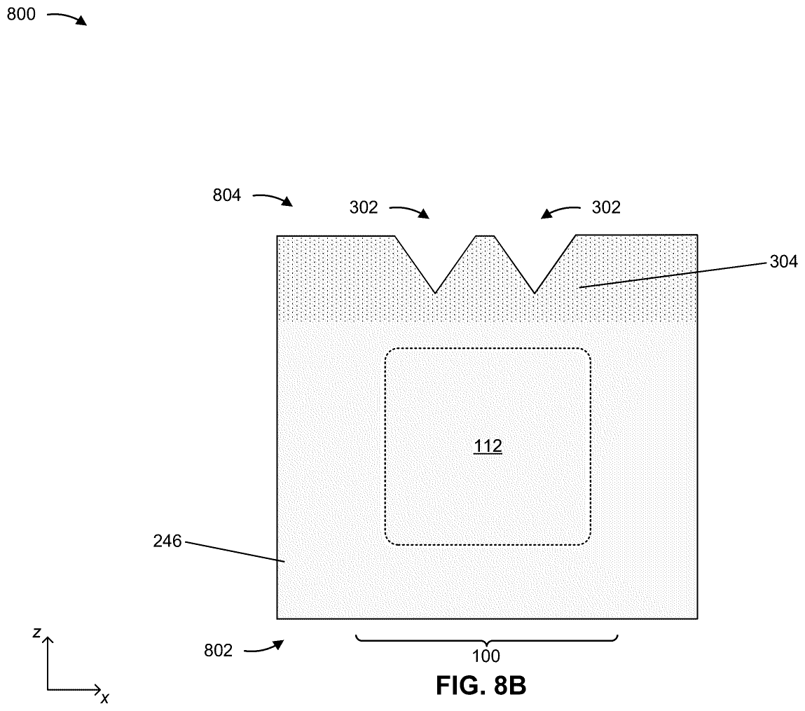

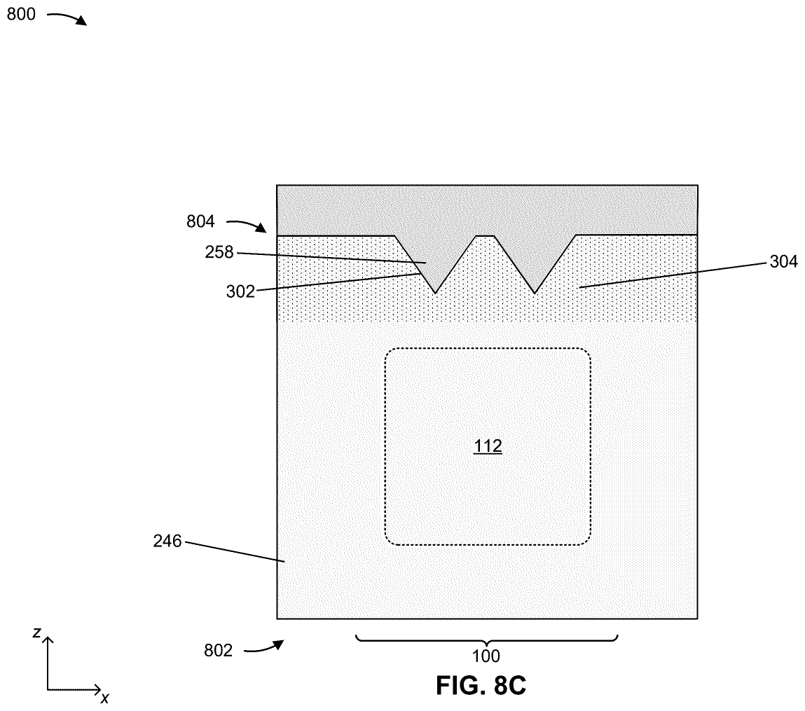

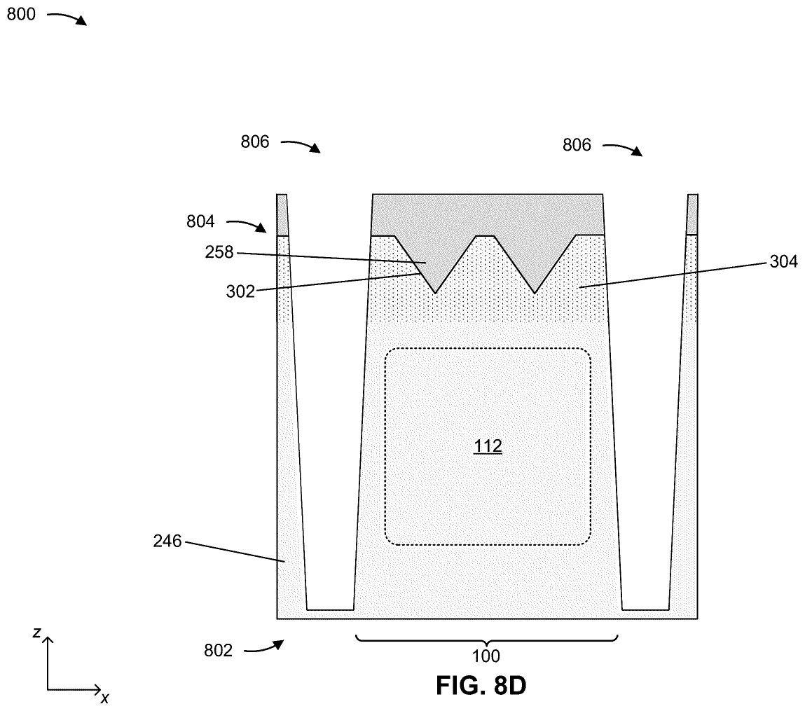

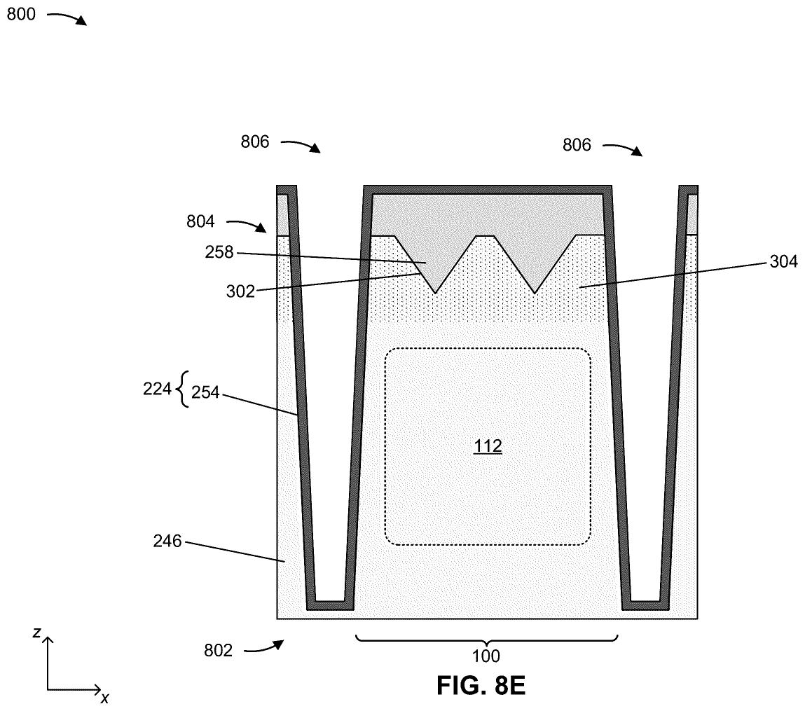

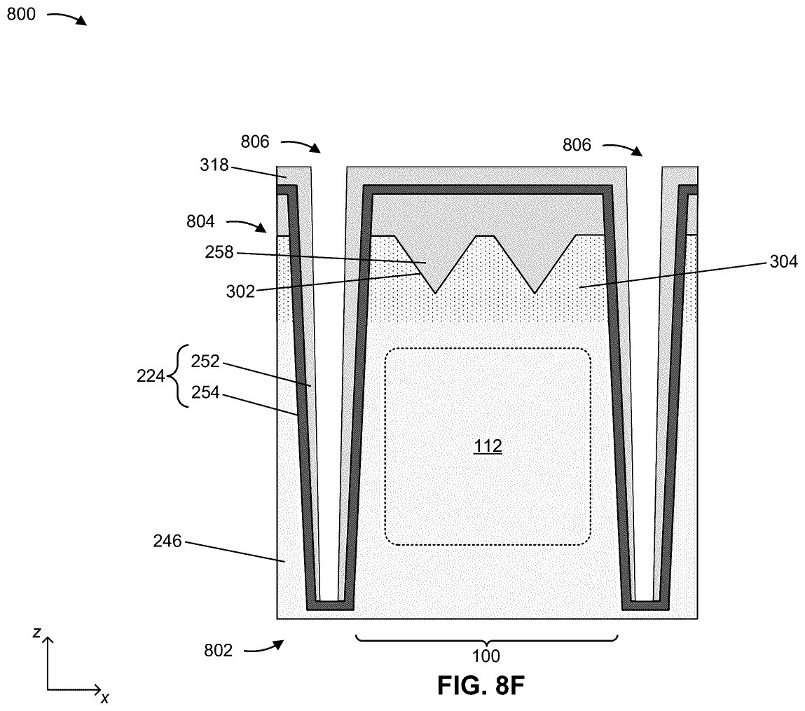

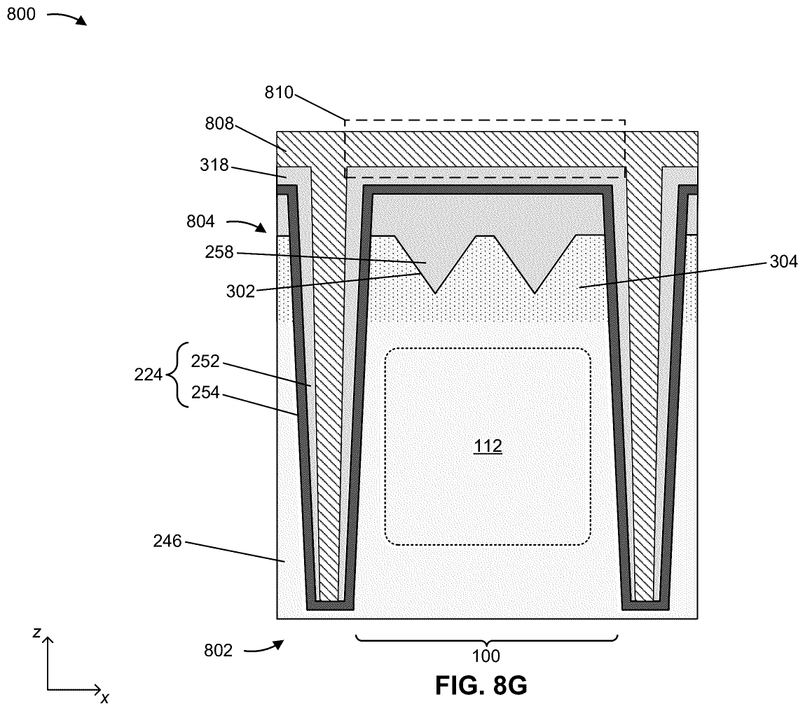

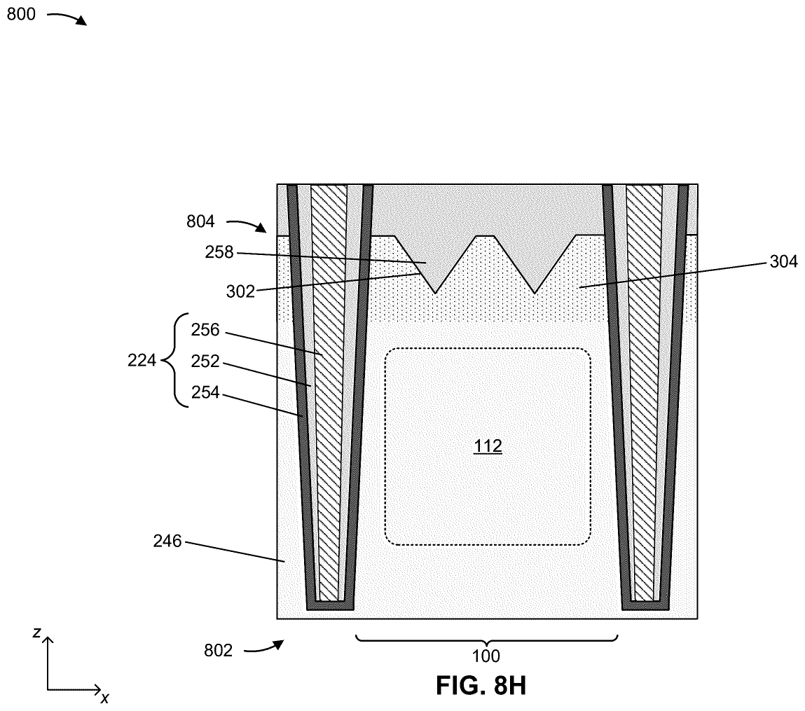

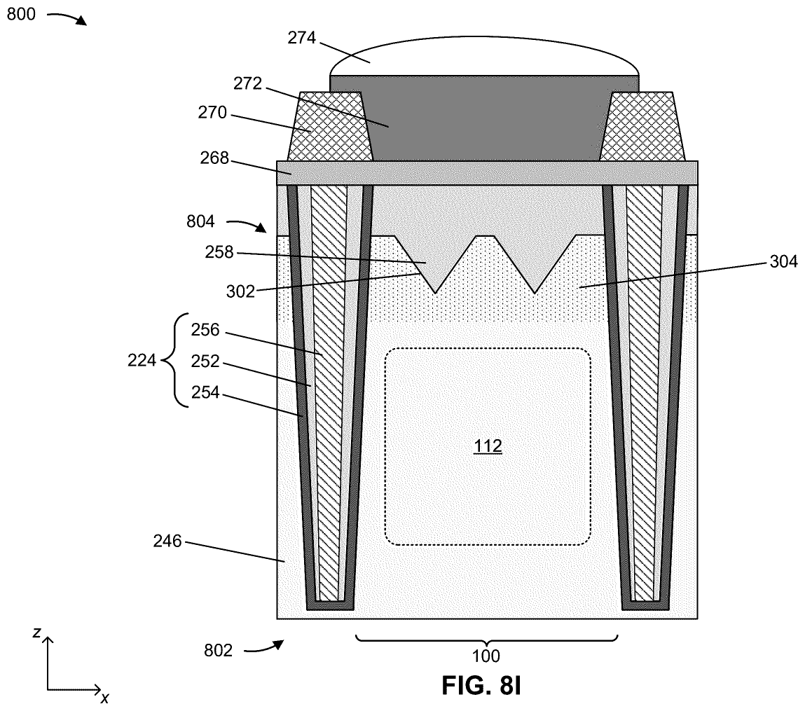

Each diffusion structure 258 is included in a recess 302 that extends into in the substrate 246. The recesses 302 are filed with a dielectric material to form the diffusion structure 258. The diffusion structures 258, therefore, extend into the backside surface of the substrate 246. The diffusion structures 258 may have a V-shaped cross-sectional profile (in which case the diffusion structures 258 may each have an inverted pyramid three-dimensional shape), a rounded or U-shaped cross-sectional profile, and/or may have another cross-sectional profile. The dielectric material may merge between the diffusion structures 258 such that the diffusion structures 258 have a substantially flat top surface on which the passivation layer 268 is included. The dielectric material of the diffusion structures 258 is included directly on (e.g., in direct physical contact with) the substrate 246 in the recesses 302, as opposed to having a liner in the recesses 302 between the substrate 246 and the dielectric material of the diffusion structures 258. This occurs, at least in part, because of the techniques used to form the DTI structure 224 and the diffusion structures 258, that are described in connection with FIGS. 8A-8H, among other examples.

As further shown in FIG. 3A, a doped implant region 304 is included in the substrate 246. The doped implant region 304 is included between the photodiode 112 and the diffusion structures 258. The doped implant region 304 may include a blanket implant region of the substrate 246 extending between opposing sides of the inner perimeter of the DTI structure 224 in a cross-section view of the pixel sensor 100. The doped implant region 304 is non-conformally doped with one or more types of dopants such that the doped implant region 304 extends between a top and a bottom of the recesses 302 in the substrate 246.

The doped implant region 304 may be included to protect the photodiode 112 from defects that may occur in the substrate 246 due to etching the substrate 246 to form the recesses 302. These defects may include dangling bonds that are passivated by the dopant(s) included in the doped implant region 304. In some implementations, the photodiode 112 includes one or more n-type dopants, and the doped implant region 304 includes one or more p-type dopants that increase the concentration of holes (e.g., positive charge carriers) to passivate the dangling bonds. This cases a positive charge to be induced on the backside surface of the substrate 246, which reduces the likelihood of leakage of photocurrent through the backside surface of the substrate 246. Examples of p-type dopants that may be included in the doped implant region 304 include boron (B), gallium (Ga), and/or indium (In), among other examples. Examples of n-type dopants include phosphorous (P), arsenic (As), and/or antimony (Sb), among other examples.

As further shown in FIG. 3A, the metal grid structure 270 may be included above the DTI structure 224 and on or above the passivation layer 268. The color filter region 272 may be included in between the metal grid structure 270.

FIG. 3B illustrates an example 306 of a pixel sensor 100, which is similar to the example 300 of the pixel sensor 100 in FIG. 3A except that the example 306 of a pixel sensor 100 includes a composite grid structure 308 instead of a metal grid structure 270. The composite grid structure 308 includes a metal layer 310 and a dielectric layer 312 on the metal layer 310.

FIG. 3C illustrates an example 314 of a pixel sensor 100, which is similar to the example 300 of the pixel sensor 100 in FIG. 3A except that the metal grid structure 270 in the example 314 of a pixel sensor 100 is encapsulated in the passivation layer 268. In other words, the metal grid structure 270 is embedded in the passivation layer 268.

FIG. 3D illustrates an example 316 of a pixel sensor 100, which is similar to the example 300 of the pixel sensor 100 in FIG. 3A except that the example 316 of a pixel sensor 100 includes a plurality of metal grid structures. For example, the example 316 of the pixel sensor 100 includes the metal grid structure 270 embedded in the passivation layer 268, and another metal grid structure 318 above the metal grid structure 270 and on the passivation layer 268.

FIG. 3E illustrates an example 320 of a pixel sensor 100, which is similar to the example 300 of the pixel sensor 100 in FIG. 3A except that the dielectric liner 254 of the DTI structure 224 continuously extends between the sections of the DTI structure 224 and over the photodiode 112 in the example 320 of the pixel sensor 100. The dielectric layer 252 of the DTI structure 224 also continuously extends between the sections of the DTI structure 224 and over the photodiode 112 as a buffer layer 322 on the dielectric liner 254. This may occur due to a planarization operation, that is performed to form the metal insert 256 of the DTI structure 224, stopping prior to removal of the buffer layer 322 and the dielectric liner 254 from over the photodiode 112.

As indicated above, FIGS. 3A-3E are provided as examples. Other examples may differ from what is described with regard to FIGS. 3A-3E.

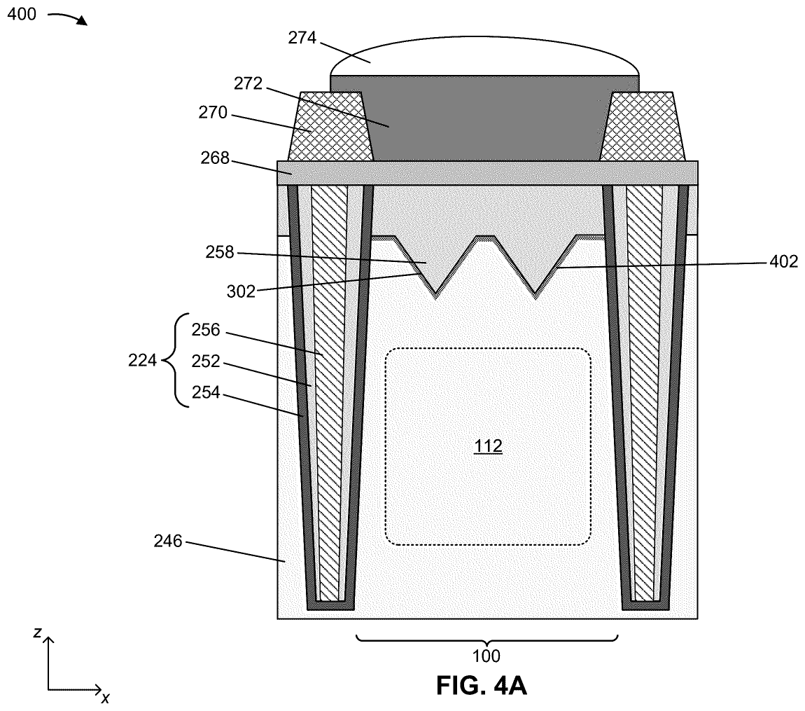

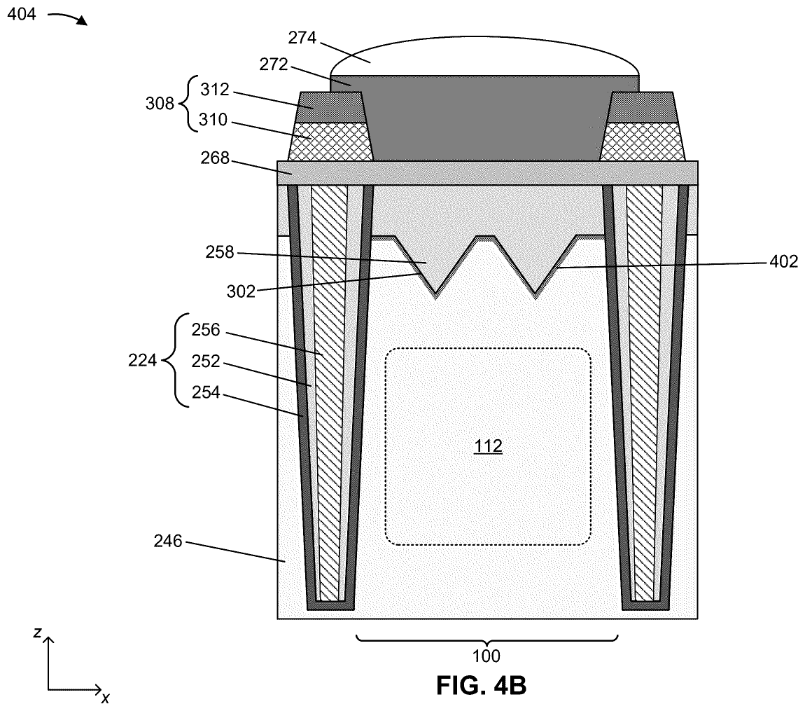

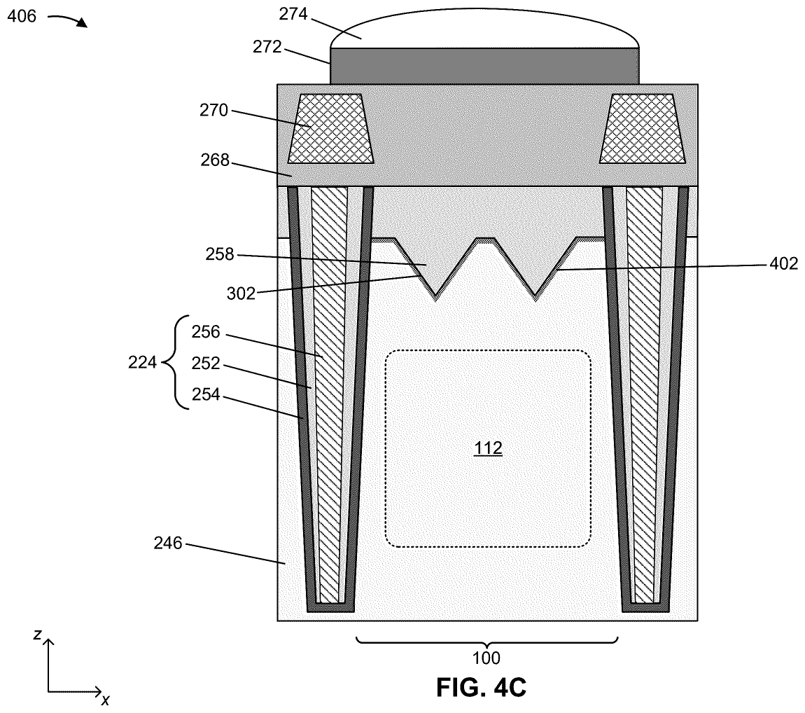

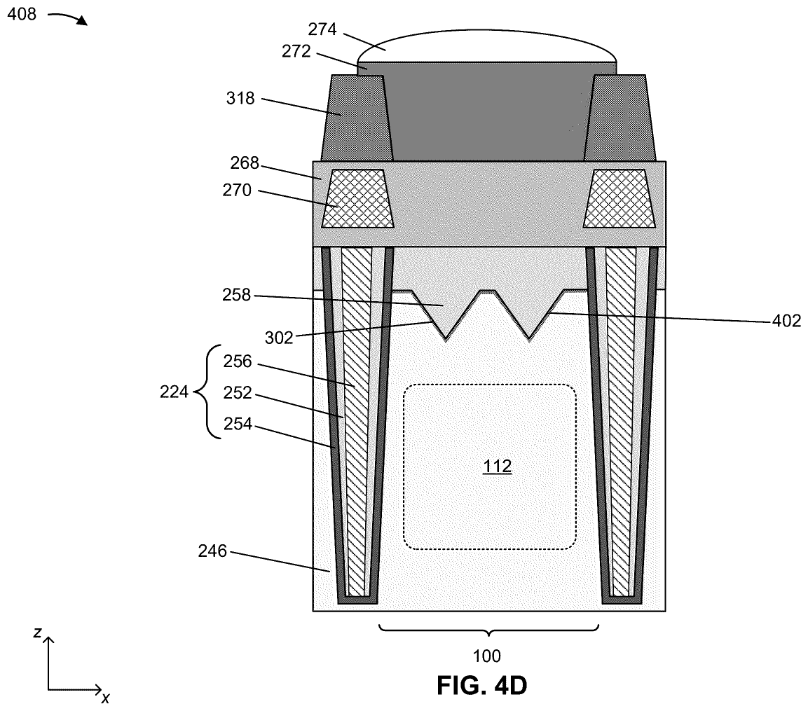

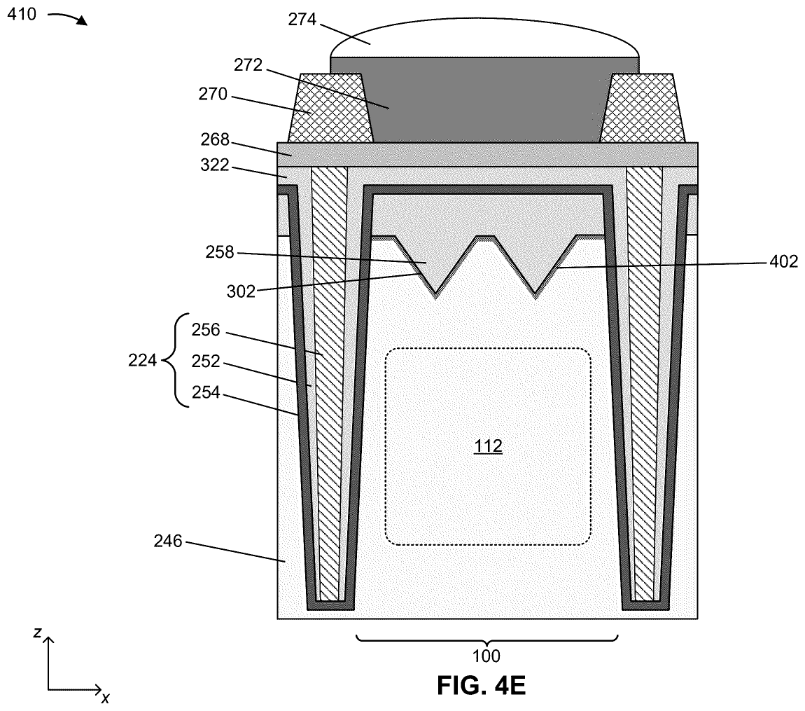

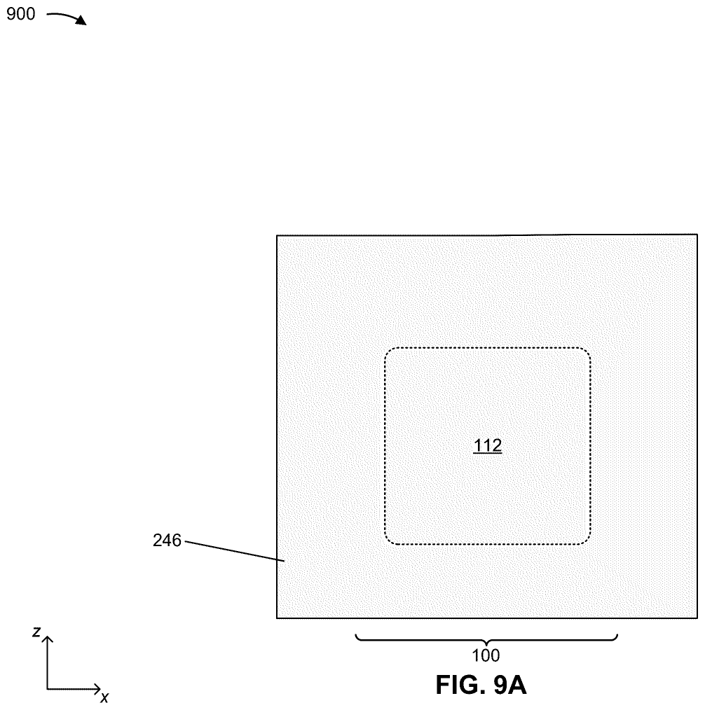

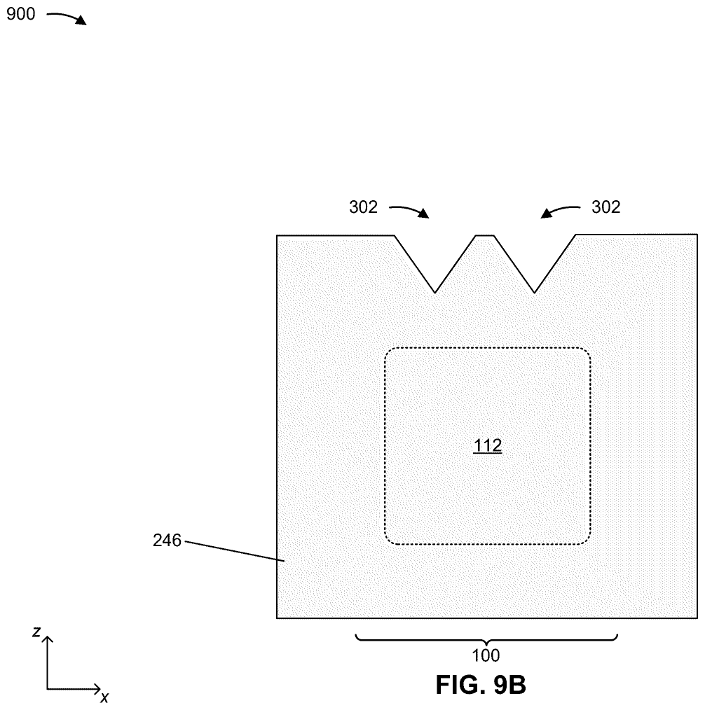

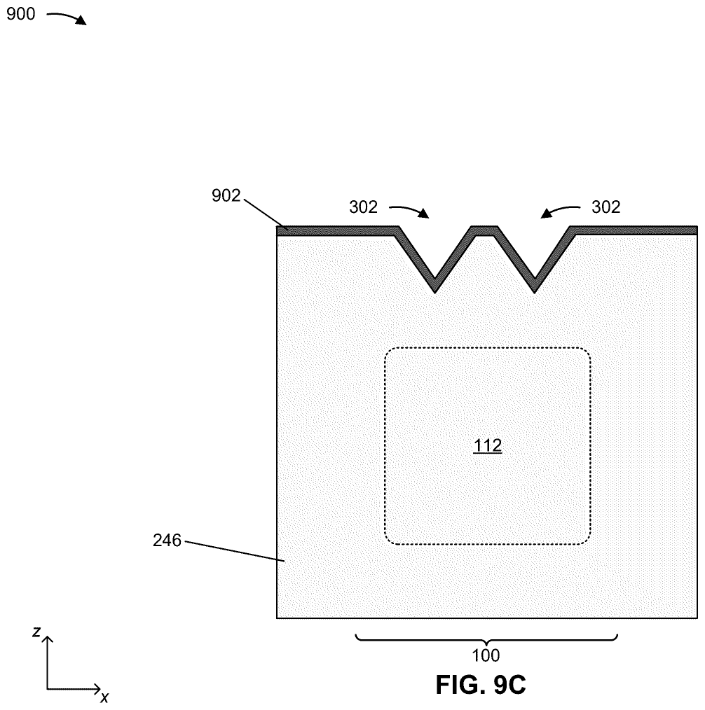

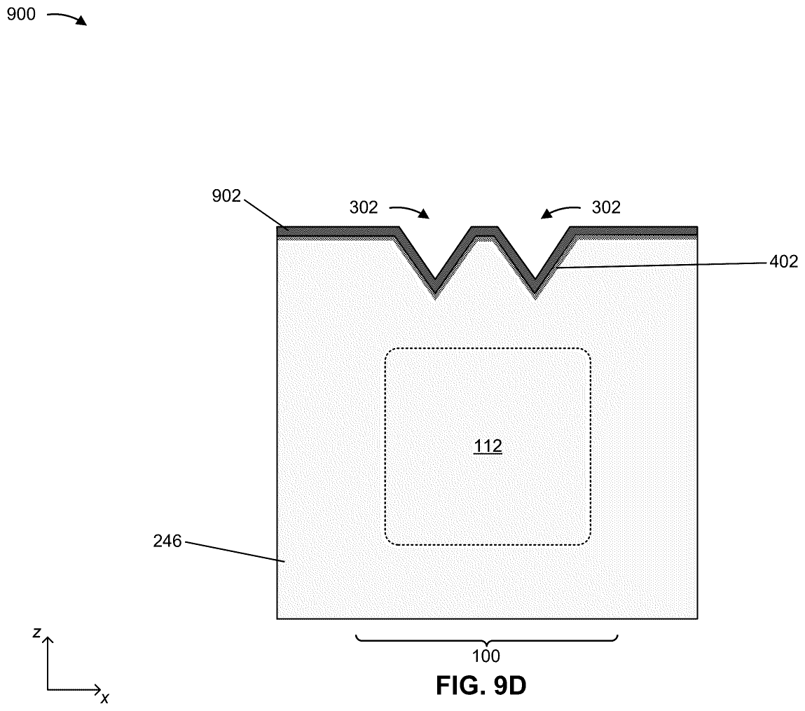

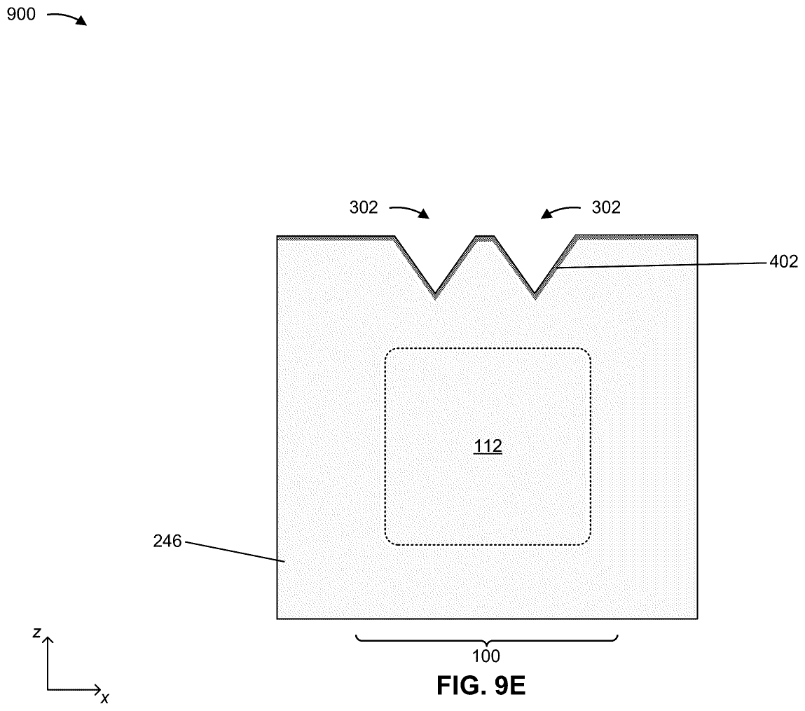

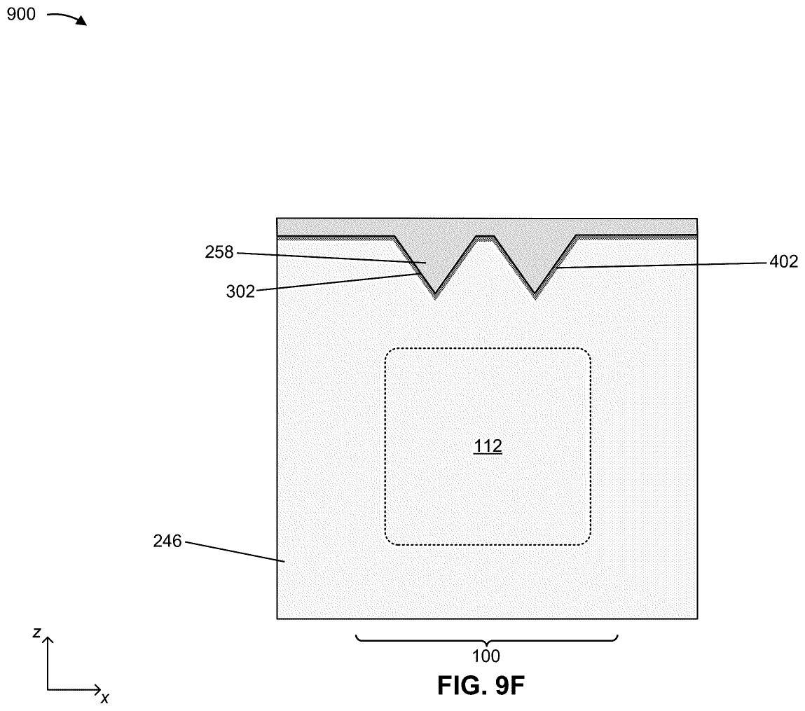

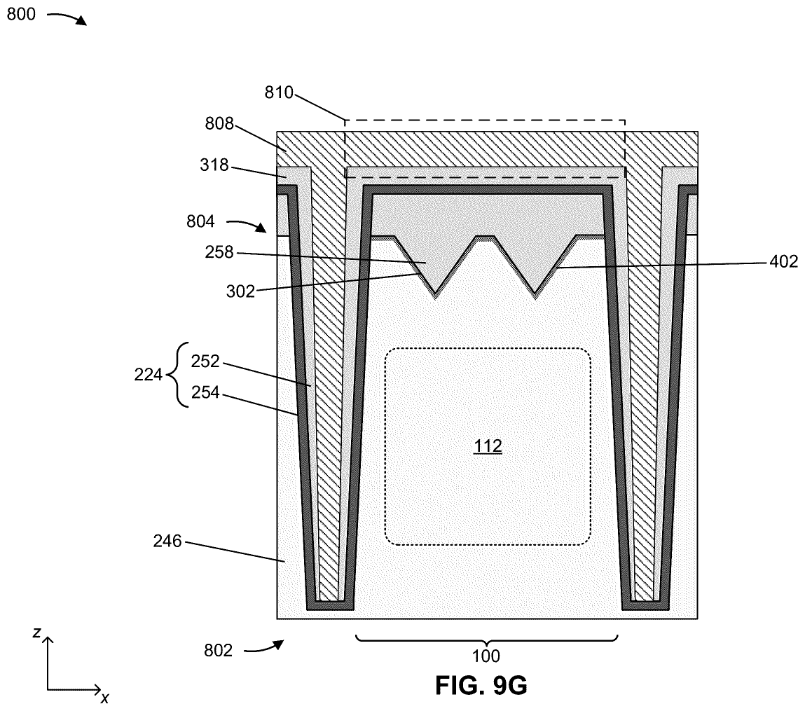

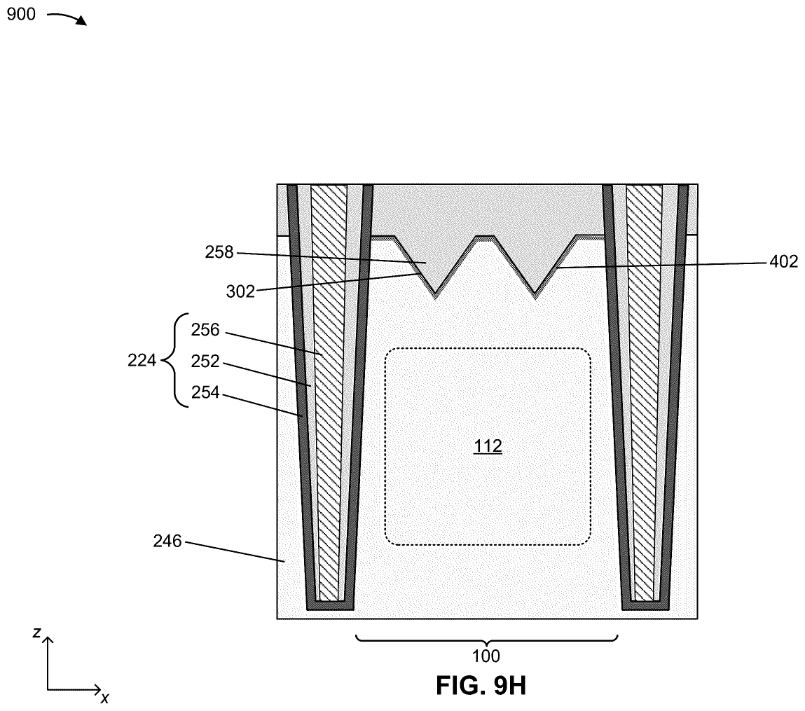

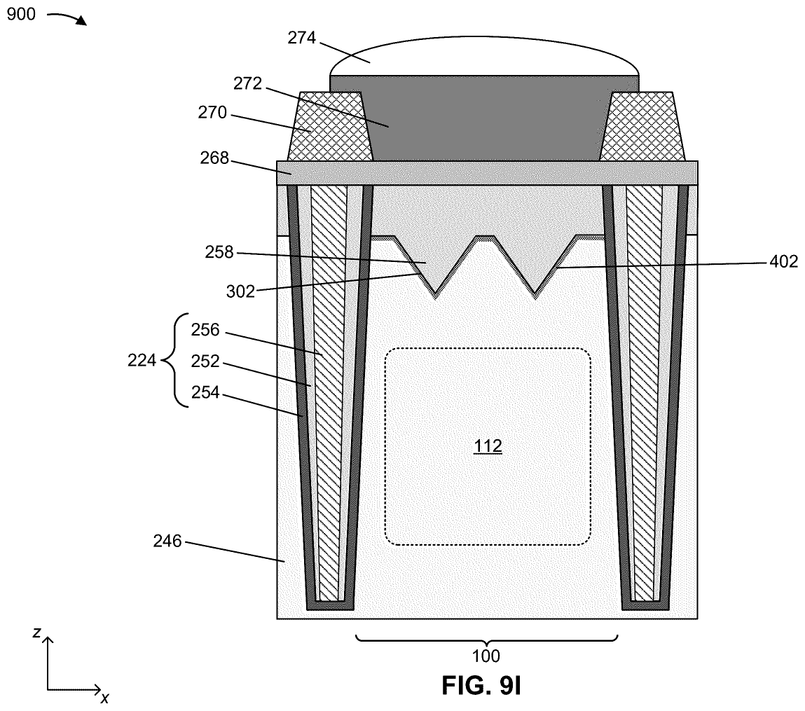

FIGS. 4A-4E are diagrams of examples of pixel sensors 100 that may be included in a pixel sensor array 222 of an image sensor device 210 described herein. As shown in FIG. 4A, an example 400 of a pixel sensor 100 is similar to the example 300 of the pixel sensor 100 in FIG. 3A. However, the example 400 of the pixel sensor 100 in FIG. 4A includes a doped implant liner 402 instead of the doped implant region 304. The doped implant liner 402 includes a conformal implant region that conforms to the profile of the recesses 302 in which the diffusion structures 258 are formed. The doped implant liner 402 performs a similar passivation function as the doped implant region 304. However, the doped implant liner 402 is formed using different semiconductor processing techniques than those used to form the doped implant region 304, such as those described in connection with FIGS. 9A-9H.

FIG. 4B illustrates an example 404 of a pixel sensor 100, which is similar to the example 400 of the pixel sensor 100 in FIG. 4A except that the example 404 of a pixel sensor 100 includes a composite grid structure 308 instead of a metal grid structure 270. The composite grid structure 308 includes a metal layer 310 and a dielectric layer 312 on the metal layer 310.

FIG. 4C illustrates an example 406 of a pixel sensor 100, which is similar to the example 400 of the pixel sensor 100 in FIG. 4A except that the metal grid structure 270 in the example 406 of a pixel sensor 100 is encapsulated in the passivation layer 268. In other words, the metal grid structure 270 is embedded in the passivation layer 268.

FIG. 4D illustrates an example 408 of a pixel sensor 100, which is similar to the example 400 of the pixel sensor 100 in FIG. 4A except that the example 316 of a pixel sensor 100 includes a plurality of metal grid structures. For example, the example 316 of the pixel sensor 100 includes the metal grid structure 270 embedded in the passivation layer 268, and another metal grid structure 318 above the metal grid structure 270 and on the passivation layer 268.

FIG. 4E illustrates an example 410 of a pixel sensor 100, which is similar to the example 400 of the pixel sensor 100 in FIG. 4A except that the dielectric liner 254 of the DTI structure 224 continuously extends between the sections of the DTI structure 224 and over the photodiode 112 in the example 320 of the pixel sensor 100. The dielectric layer 252 of the DTI structure 224 also continuously extends between the sections of the DTI structure 224 and over the photodiode 112 as a buffer layer 322 on the dielectric liner 254. This may occur due to a planarization operation, that is performed to form the metal insert 256 of the DTI structure 224, stopping prior to removal of the buffer layer 322 and the dielectric liner 254 from over the photodiode 112.

As indicated above, FIGS. 4A-4E are provided as examples. Other examples may differ from what is described with regard to FIGS. 4A-4E.

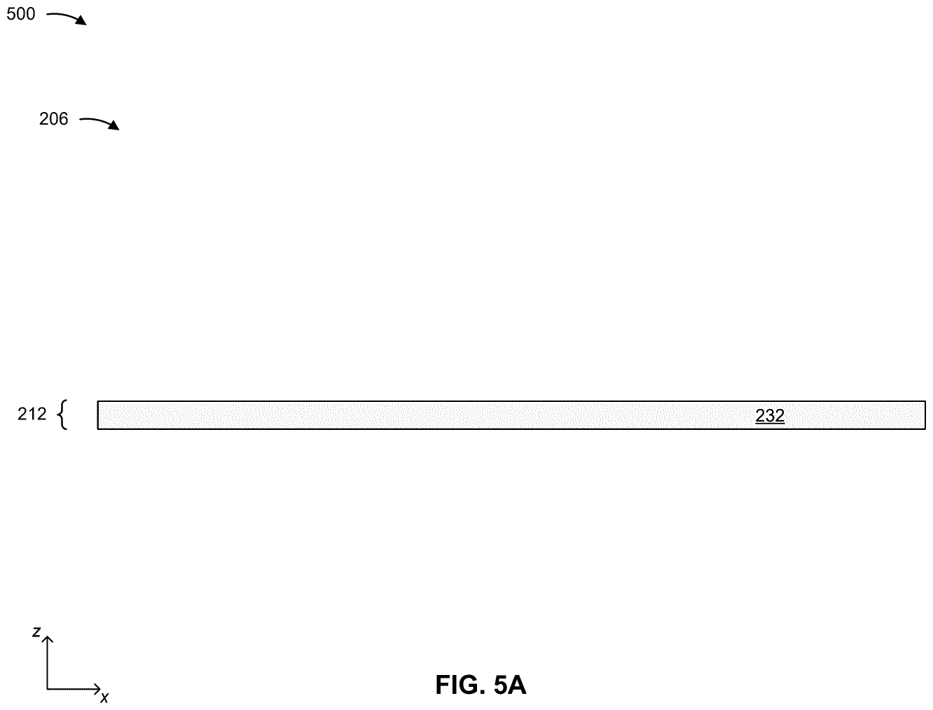

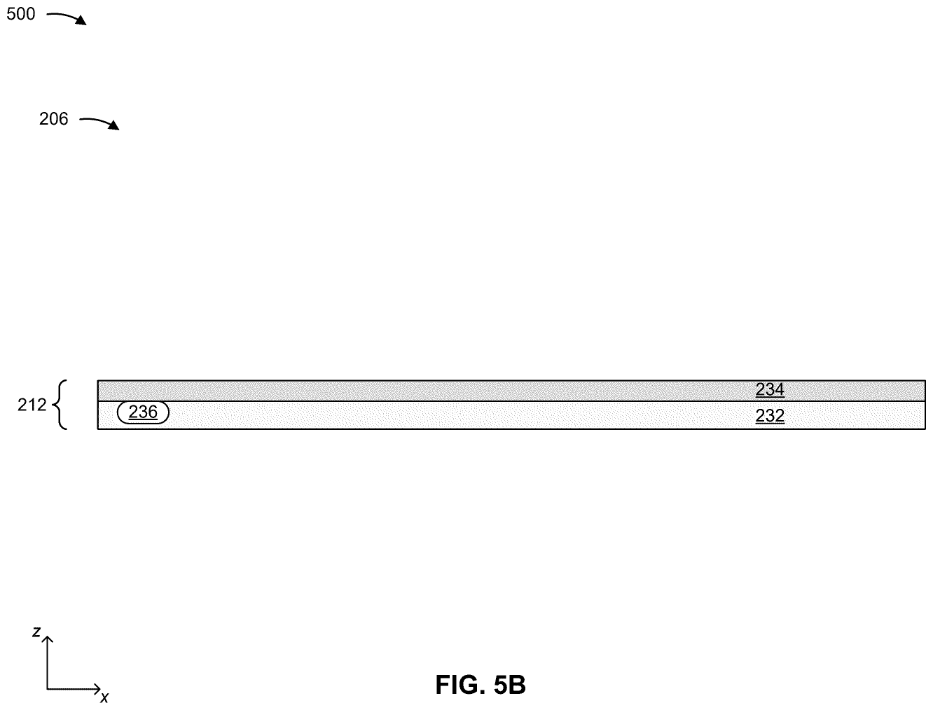

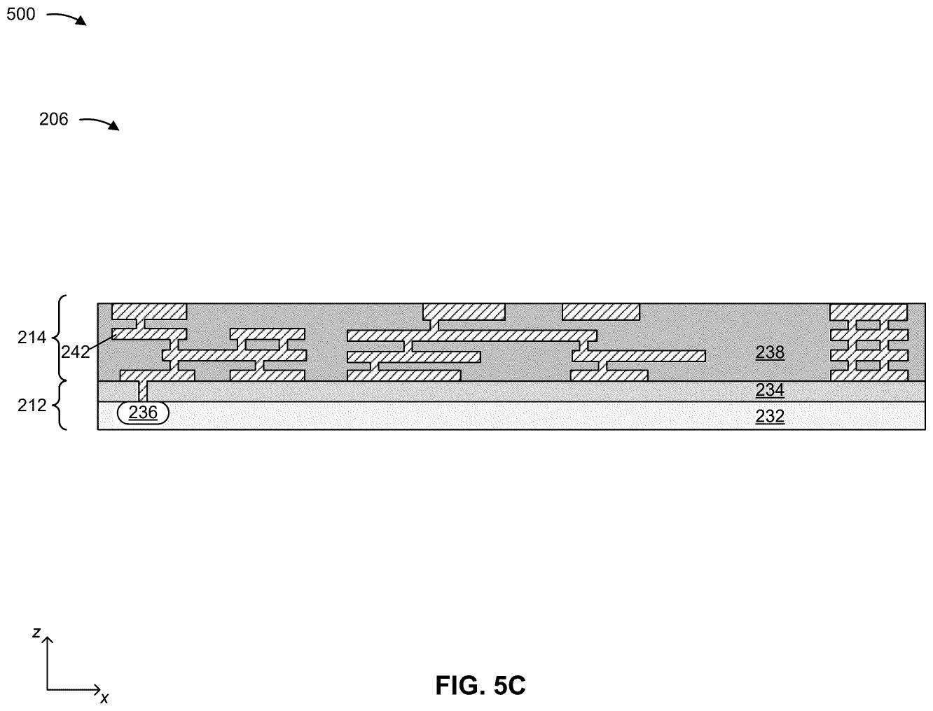

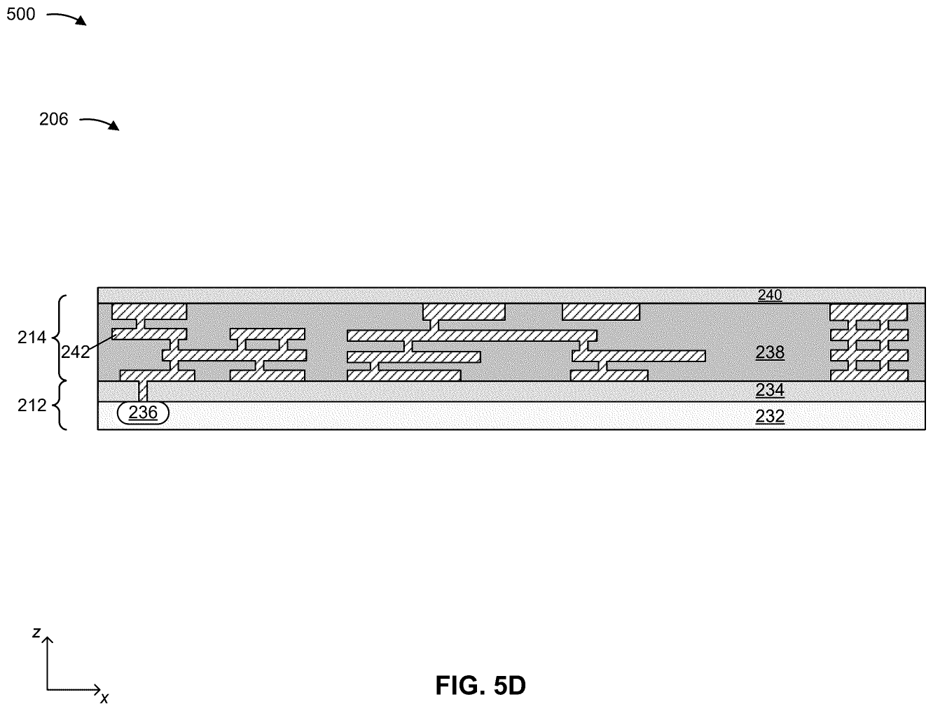

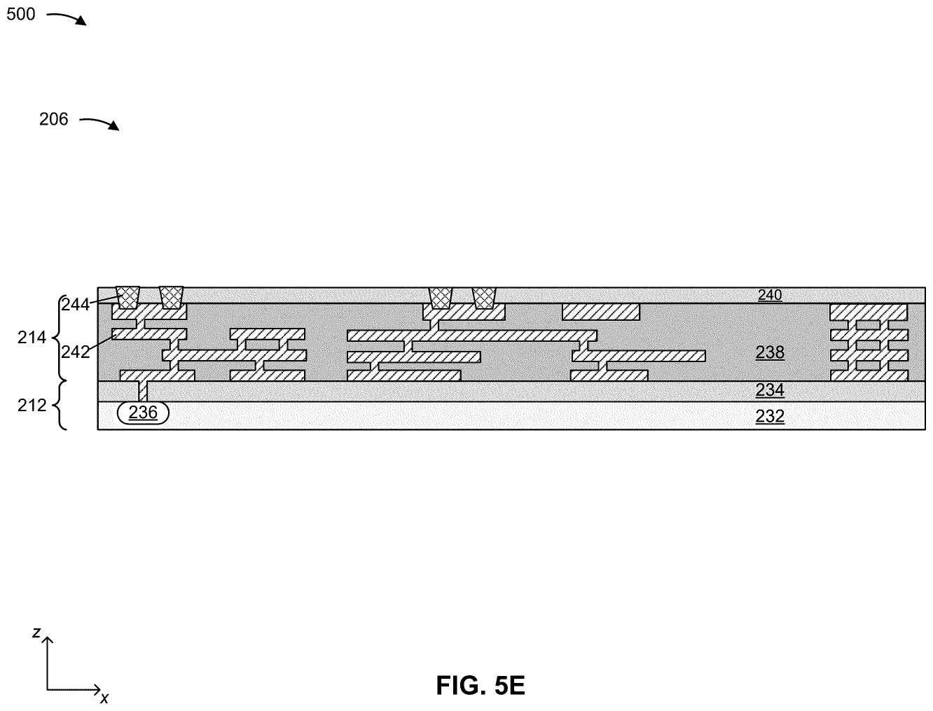

FIGS. 5A-5E are diagrams of an example implementation 500 of forming a circuitry die 206 (or a portion thereof) described herein. In some implementations, one or more of the semiconductor processing operations described in connection with FIGS. 5A-5E may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 5A, the substrate 232 of the device layer 212 of the circuitry dic 206 is provided. The substrate 232 may be provided in the form of a semiconductor wafer such as a silicon (Si) wafer may be provided as an SOI wafer, and/or another type of semiconductor work piece.

As shown in FIG. 5B, one or more devices 236 may be formed in and/or on the substrate 232. One or more semiconductor processing tools may be used to form one or more portions of the devices 236. For example, a deposition tool may be used to perform various deposition operations to deposit layers of the devices 236, and/or to deposit photoresist layers for etching the substrate 232 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 232 and/or portions of the deposited layers to form the devices 236. As another example, a planarization tool may be used to planarize portions of the devices 236. As another example, a plating tool may be used to deposit metal structures and/or layers of the devices 236.

As further shown in FIG. 5B, a dielectric layer 234 may be deposited over and/or on the substrate 232 and over and/or on the devices 236. A deposition tool may be used to deposit the dielectric layer 234 using a physical vapor deposition (PVD) technique, an atomic layer deposition (ALD) technique, a chemical vapor deposition (CVD) technique, an oxidation technique, another type of deposition technique. In some implementations, a planarization tool may be used to planarize the dielectric layer 234 after the dielectric layer 234 is deposited.

As shown in FIG. 5C, a first portion of an interconnect layer 214 of the circuitry die 206 is formed above the device layer 212. To form the first portion of the interconnect layer 214, a deposition tool may be used to deposit a dielectric layer 238 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 238 after the dielectric layer 238 is deposited.

A deposition tool, an exposure tool, a developer tool, an etch tool, a planarization tool, a plating tool, and/or another semiconductor processing tool may be used to perform various operations to form interconnect structures 242 in the first portion of the interconnect layer 214. A deposition tool and/or a plating tool may be used to deposit the interconnect structures 242 using a PVD technique, an ALD technique, a CVD technique, an electroplating technique, and/or another deposition technique. In some implementations, a planarization tool may be used to planarize the interconnect structures 242 after the interconnect structures 242 are deposited.

In some implementations, first portion of the interconnect layer 214 is built up in the z-direction in a plurality of via layers (V-layers) and metallization layers (M-layers). For example, a first portion of the dielectric layer 238 may be formed, recesses may be formed in the first portion of the dielectric layer 238, and first interconnect structures 242 (e.g., a VO via layer, an MO metallization layer) may be formed in the recesses. A second portion of the dielectric layer 238 may be formed, recesses may be formed in the second portion of the dielectric layer 238, and second interconnect structures 242 (e.g., a VI via layer, an MI metallization layer) may be formed in the recesses. The remaining via layers and/or metallization layers of the first portion of the interconnect layer 214 may be formed in a similar manner.

As shown in FIGS. 5D and 5E, a second portion of the interconnect layer 214 may be formed, and the second portion of the interconnect layer 214 may include a bonding layer 240 and bonding structures 244. As shown in FIG. 5D, the bonding layer 240 may be formed over and/or on the dielectric layer 238, and over and/or on the top-most interconnect structures 242. A deposition tool may be used to deposit the bonding layer 240 using a PVD technique, an ALD technique, a CVD technique, an oxidation technique, another deposition technique. In some implementations, a planarization tool may be used to planarize the bonding layer 240 after the bonding layer 240 is deposited.

As shown in FIG. 5E, the bonding structures 244 may be formed in the bonding layer 240. For example, a deposition tool, an exposure tool, and a developer tool may be used to form a patterned masking layer on the bonding layer 240. An etch tool may be used to etch the bonding layer 240 (e.g., using a wet etch technique, a dry etch technique) to form recesses in the bonding layer 240. A deposition tool and/or a plating tool may be used to deposit the bonding structures 244 in the recess using a CVD technique, a PVD technique, an ALD technique, an electroplating technique, and/or another deposition technique. In some implementations, a planarization tool may perform a planarization operation to planarize the bonding structures 244 after the bonding structures 244 are deposited.

As indicated above, FIGS. 5A-5E are provided as an example. Other examples may differ from what is described with regard to FIGS. 5A-5E.

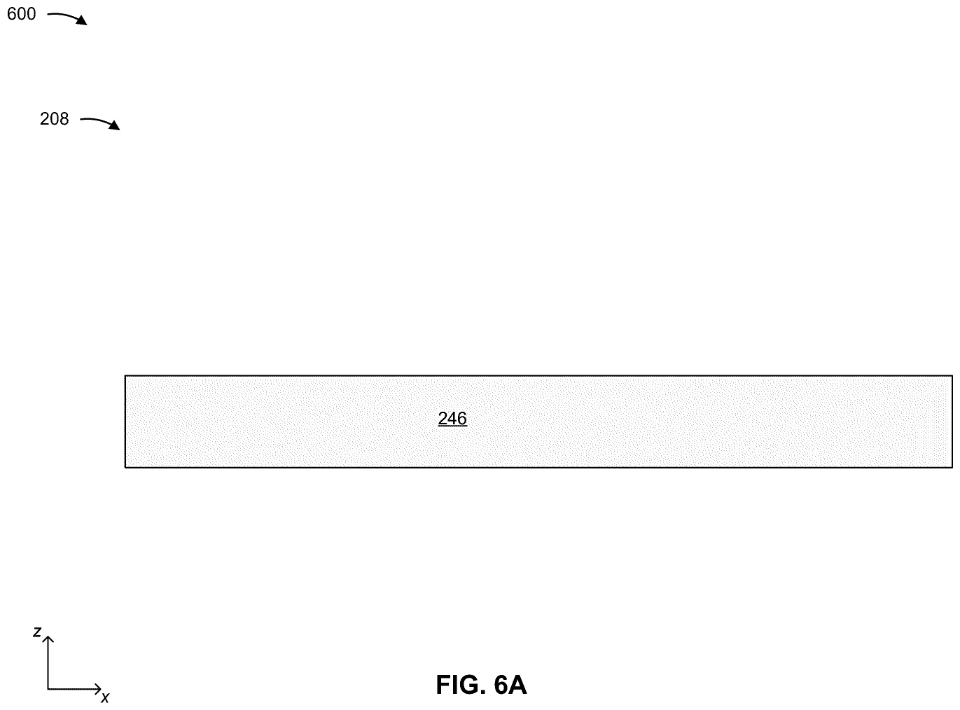

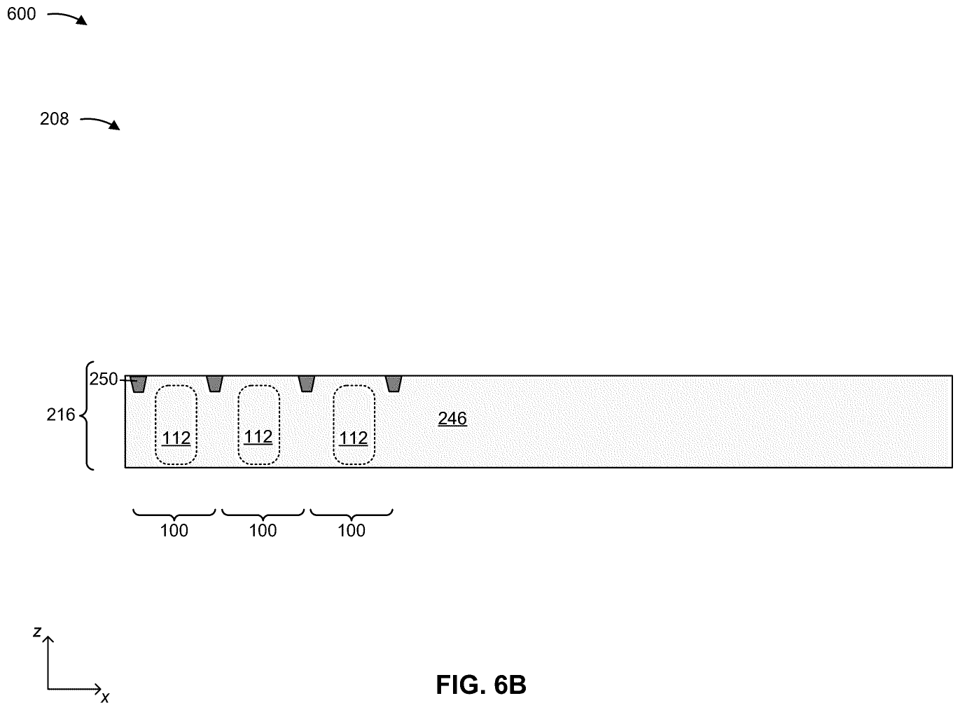

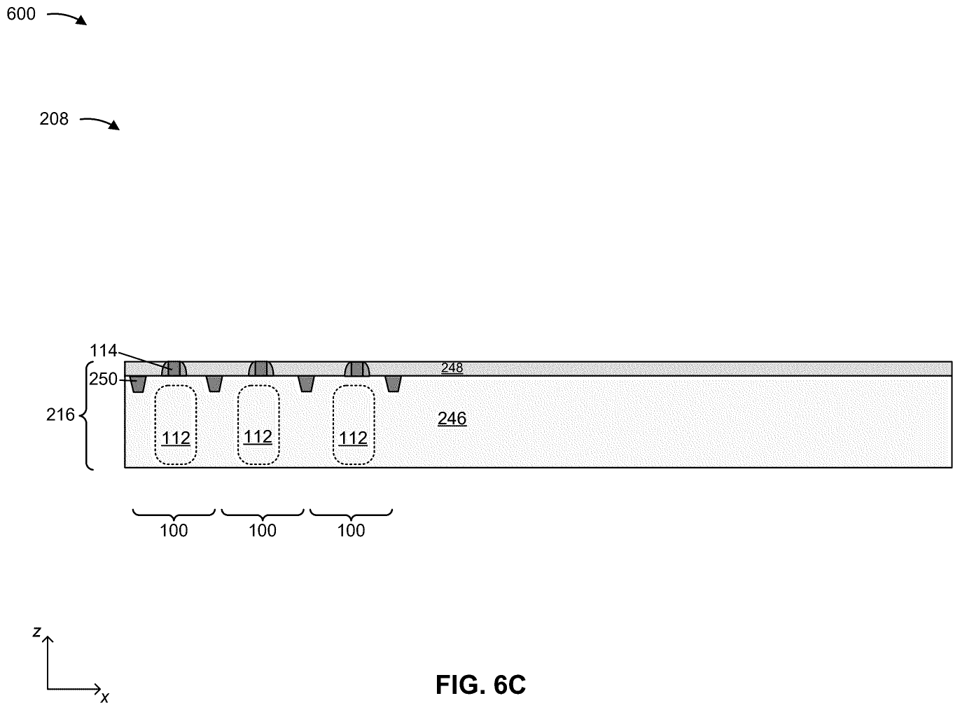

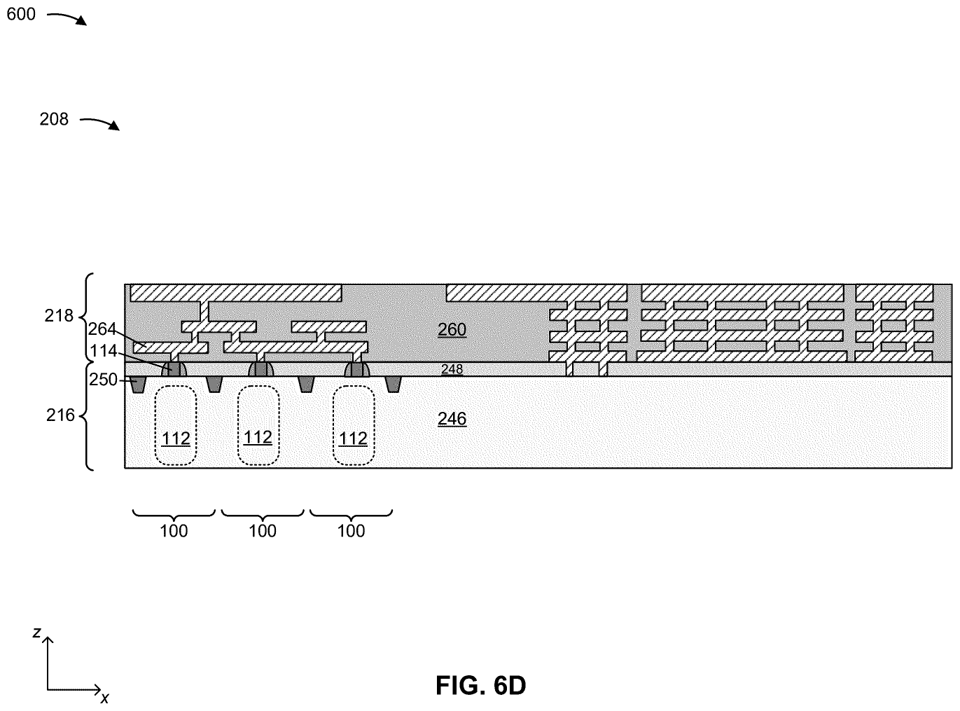

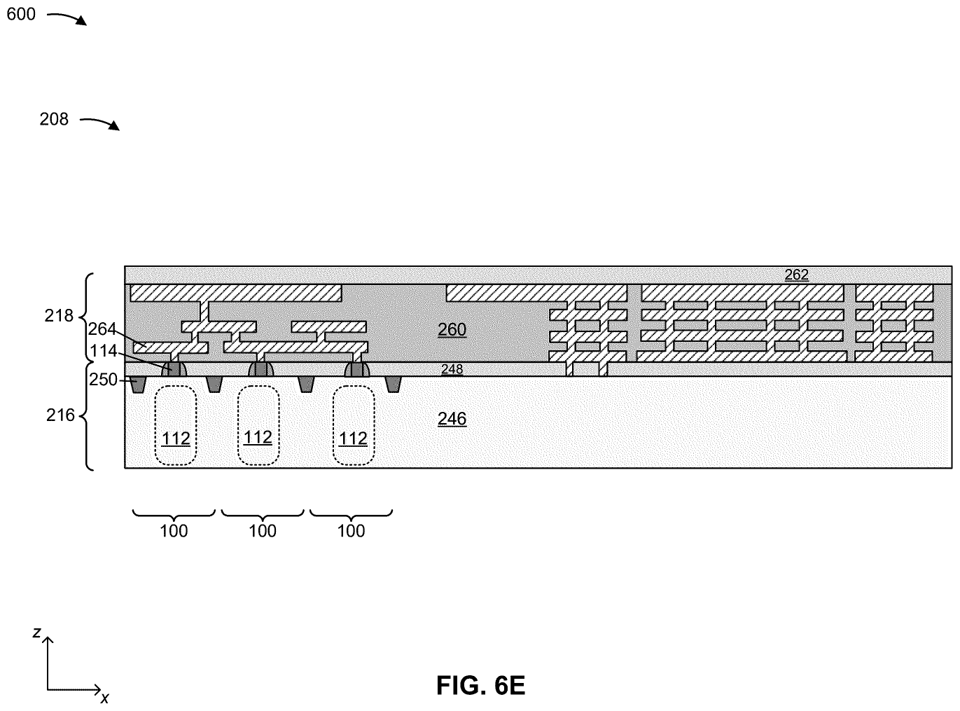

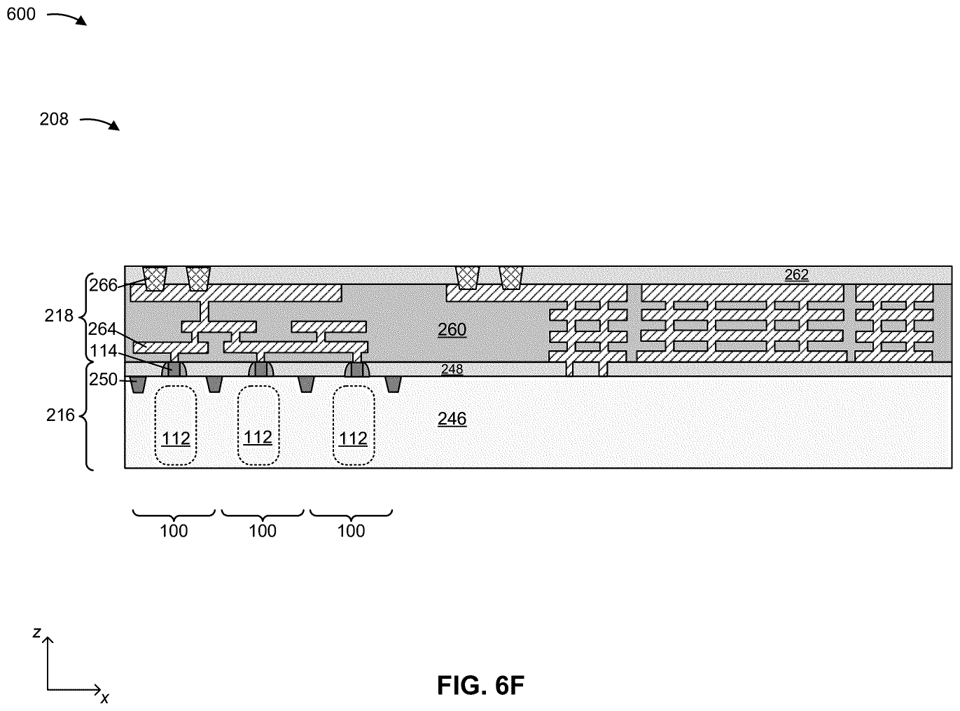

FIGS. 6A-6F are diagrams of an example implementation 600 of forming a sensor die 208 (or a portion thereof) described herein. In some implementations, one or more of the semiconductor processing operations described in connection with FIGS. 6A-6F may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 6A, the substrate 246 of the device layer 216 of the sensor die 208 is provided. The substrate 246 may be provided in the form of a semiconductor wafer such as a silicon (Si) wafer may be provided as an SOI wafer, and/or another type of semiconductor work piece.

As shown in FIG. 6B, photodiodes 112 of pixel sensors 100 of a pixel sensor array 222 of the sensor die 208 may be formed in the substrate 246 from the front side of the substrate 246. In some implementations, an ion implantation tool may be used to implant ions into the substrate 246 to form a P-N junction between a p-doped region of the substrate 246 and an n-doped region of the substrate 246, or to form a P-I-N junction between p-doped region of the substrate 246, an n-doped region of the substrate 246, and an intrinsic (e.g., undoped) semiconductor region for a photodiode 112.

In some implementations, an ion implantation tool may be used to implant dopants (e.g., p-type dopants, n-type dopants) into the substrate 246 from the front side of the substrate 246 to form the doped implant region 304 prior to formation of the photodiodes 112. In some implementations, an ion implantation tool may be used to implant dopants (e.g., p-type dopants, n-type dopants) into the substrate 246 from the front side of the substrate 246 to form the doped implant region 304 after formation of the photodiodes 112.

As further shown in FIG. 6B, STI structures 250 may be formed in the substrate 246 (e.g., from the front side of the substrate 246) such that the STI structures 250 are located between the photodiodes 112. In some implementations, the STI structures 250 are formed after the photodiodes 112 are formed. In some implementations, the STI structures 250 are formed prior to formation of the photodiodes 112. A deposition tool, an exposure tool, and a developer tool may be used to form a patterned masking layer on the substrate 246. An etch tool may be used to etch into the substrate 246 from the front side of the substrate 246 (e.g., using a wet etch technique, a dry etch technique) to form the recesses in the front side of the substrate 246. A deposition tool may be used to deposit the STI structures 250 in the recesses using a CVD technique, a PVD technique, an ALD technique, an oxidation technique, and/or another deposition technique. In some implementations, a planarization tool may perform a planarization operation to planarize the STI structures 250 after the STI structures 250 are deposited.

As shown in FIG. 6C, transfer gates 114 of the pixel sensors 100 may be formed over and/or on the front side surface of the substrate 246. Forming a transfer gate 114 may include deposing a gate dielectric on the front side surface of the substrate 246, depositing a gate electrode on the gate dielectric layer, and/or forming sidewall spacers on sidewalls of the gate electrode, among other examples.

As further shown in FIG. 6C, a dielectric layer 248 may be formed over and/or on the front side of the substrate 246, and over and/or on the transfer gates 114. A deposition tool may be used to deposit the dielectric layer 248 using a CVD technique, a PVD technique, an ALD technique, an electroplating technique, and/or another deposition technique. In some implementations, a planarization tool may perform a planarization operation to planarize the dielectric layer 248 after the dielectric layer 248 is deposited.

As shown in FIG. 6D, a first portion of an interconnect layer 218 of the sensor die 208 is formed above the device layer 216. To form the first portion of the interconnect layer 218, a deposition tool may be used to deposit a dielectric layer 260 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 260 after the dielectric layer 260 is deposited.

A deposition tool, an exposure tool, a developer tool, an etch tool, a planarization tool, a plating tool, and/or another semiconductor processing tool may be used to perform various operations to form interconnect structures 264 in the first portion of the interconnect layer 218. A deposition tool and/or a plating tool may be used to deposit the interconnect structures 264 using a PVD technique, an ALD technique, a CVD technique, an electroplating technique, and/or another deposition technique. In some implementations, a planarization tool may be used to planarize the interconnect structures 264 after the interconnect structures 264 are deposited.

In some implementations, first portion of the interconnect layer 218 is built up in the z-direction in a plurality of via layers (V-layers) and metallization layers (M-layers). For example, a first portion of the dielectric layer 260 may be formed, recesses may be formed in the first portion of the dielectric layer 260, and first interconnect structures 264 (e.g., a VO via layer, an MO metallization layer) may be formed in the recesses. A second portion of the dielectric layer 260 may be formed, recesses may be formed in the second portion of the dielectric layer 260, and second interconnect structures 264 (e.g., a VI via layer, an MI metallization layer) may be formed in the recesses. The remaining via layers and/or metallization layers of the first portion of the interconnect layer 218 may be formed in a similar manner.

As shown in FIGS. 6E and 6F, a second portion of the interconnect layer 218 may be formed, and the second portion of the interconnect layer 218 may include a bonding layer 262 and bonding structures 266. As shown in FIG. 6E, the bonding layer 262 may be formed over and/or on the dielectric layer 260, and over and/or on the top-most interconnect structures 264. A deposition tool may be used to deposit the bonding layer 262 using a PVD technique, an ALD technique, a CVD technique, an oxidation technique, another deposition technique. In some implementations, a planarization tool may be used to planarize the bonding layer 262 after the bonding layer 262 is deposited.

As shown in FIG. 6F, the bonding structures 266 may be formed in the bonding layer 262. For example, a deposition tool, an exposure tool, and a developer tool may be used to form a patterned masking layer on the bonding layer 262. An etch tool may be used to etch the bonding layer 262 (e.g., using a wet etch technique, a dry etch technique) to form recesses in the bonding layer 262. A deposition tool and/or a plating tool may be used to deposit the bonding structures 266 in the recess using a CVD technique, a PVD technique, an ALD technique, an electroplating technique, and/or another deposition technique. In some implementations, a planarization tool may perform a planarization operation to planarize the bonding structures 266 after the bonding structures 266 are deposited.

As indicated above, FIGS. 6A-6F are provided as an example. Other examples may differ from what is described with regard to FIGS. 6A-6F.

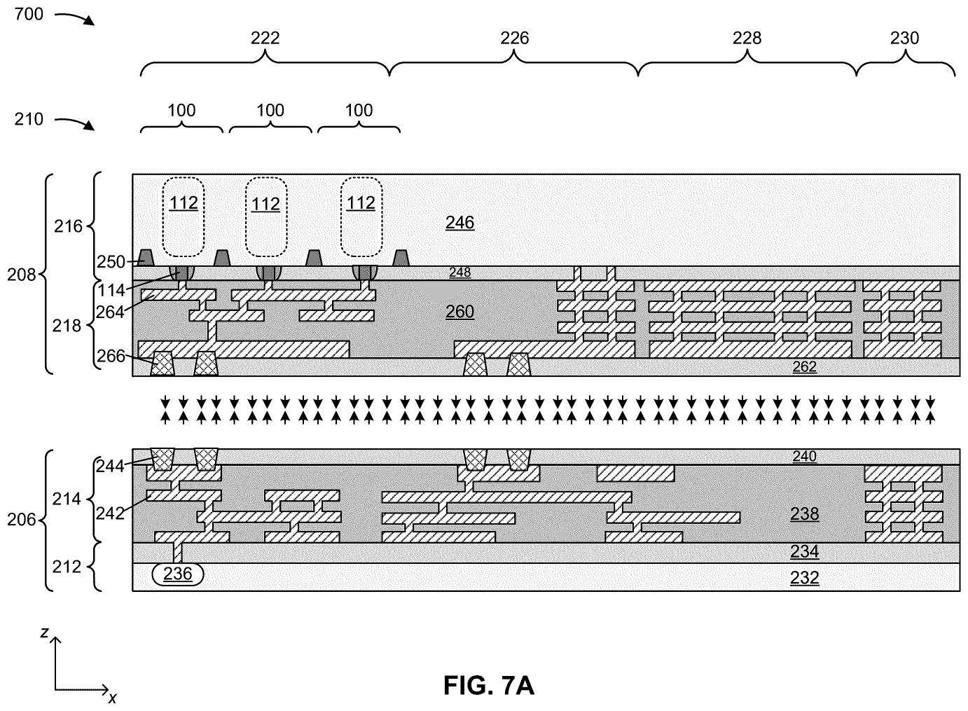

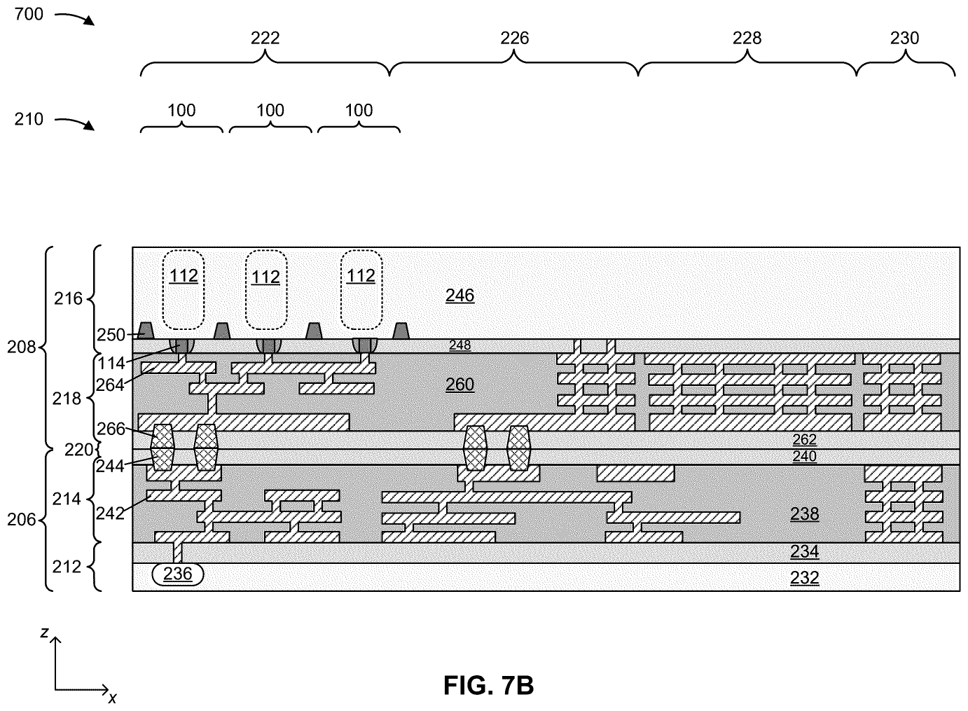

FIGS. 7A and 7B are diagrams of an example implementation 700 of forming an image sensor device 210 (or a portion thereof) described herein. In some implementations, one or more of the semiconductor processing operations described in connection with FIGS. 7A and 7B may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIGS. 7A and 7B, a bonding operation is performed to bond a circuitry die 206 and a sensor die 208 to form the image sensor device 210. The circuitry die 206 and the sensor die 208 may be bonded at a bonding interface 220, which may include the bonding layers 240 and 262 (respectively of the circuitry die 206 and the sensor die 208), and the bonding structures 244 and 266 (respectively of the circuitry die 206 and the sensor die 208). A bonding tool may be used to form a dielectric-to-dielectric bond between the bonding layers 240 and 262 at the bonding interface 220, and to form a metal-to-metal bond between the bonding structures 244 and 266 at the bonding interface 220.

As shown in FIG. 7B, after bonding, the circuitry die 206 and the sensor die 208 are stacked or vertically arranged in the z-direction in the image sensor device 210. The interconnect layer 214 of the circuitry die 206 and the interconnect layer 218 of the sensor die 208 are facing toward each other in the image sensor device 210, and the device layer 212 of the circuitry die 206 and the device layer 216 of the sensor die 208 are facing away from each other.

As indicated above, FIGS. 7A and 7B are provided as an example. Other examples may differ from what is described with regard to FIGS. 7A and 7B.

FIGS. 8A-8I are diagrams of an example implementation 800 of forming a pixel sensor array 222 of a sensor die 208 (or a portion thereof) described herein. In some implementations, one or more of the semiconductor processing operations described in connection with FIGS. 8A-8I may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 8A, an ion implantation tool may be used to implant dopants into the substrate 246 from a first side 802 of the substrate 246 (e.g., a front side of the substrate 246) to form the photodiode 112 of a pixel sensor 100 of the pixel sensor array 222. As further shown in FIG. 8A, an ion implantation tool may be used to implant dopants (e.g., p-type dopants, n-type dopants) into the substrate 246 from the first side 802 (e.g., the front side) of the substrate 246 to form the doped implant region 304 (e.g., a blanket implant region) in the substrate 246. The doped implant region 304 may be formed such that the doped implant region 304 is located at a second side 804 (e.g., a backside) of the substrate 246 opposing the first side.

In some implementations, the doped implant region 304 is formed in the substrate 246 prior to formation of the photodiode 112 (e.g., prior to the operations described in connection with FIG. 6B). In some implementations, an ion implantation tool may be used to implant dopants (e.g., p-type dopants, n-type dopants) into the substrate 246 from the first side 802 (e.g., the front side) of the substrate 246 to form the doped implant region 304 after formation of the photodiodes 112 (e.g., after the operations described in connection with FIG. 6B). Additional operations described in FIGS. 6C-6F, 7A, and/or 7B may be subsequently performed.

As shown in FIGS. 8B-8I, back side processing may be performed after additional operations described in FIGS. 6C-6F, 7A, and/or 7B are performed. As shown in FIG. 8B, the recesses 302 for the diffusion structures 258 of the pixel sensor 100 may be formed in the second side 804 (e.g., the back side) of the substrate 246. The recesses 302 may extend into the second side 804 and into the doped implant region 304 above the photodiode 112. The doped implant region 304 passivates damage to the substrate 246 that occurs during formation of the recesses 302.

In some implementations, a pattern in a photoresist layer is used to etch the second side 804 of the substrate 246 to form the recesses 302. In these implementations, a deposition tool may be used to form the photoresist layer on the second side 804 of the substrate 246. An exposure tool may be used to expose the photoresist layer to a radiation source to pattern the photoresist layer. A developer tool may be used to develop and remove portions of the photoresist layer to expose the pattern. An etch tool may be used to etch into the doped implant region 304 of the substrate 246 from the second side 804 of the substrate based on the pattern to form the recesses 302. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate 246 based on a pattern.

As shown in FIG. 8C, the recesses 302 are filled with dielectric material to form the diffusion structures 258 in the recesses 302 above the photodiode 112. In this way, the diffusion structures 258 are formed on the second side 804 (e.g., the back side) of the substrate 246 such that the diffusion structures 258 extend into the doped implant region 304. A deposition tool may be used to deposit the dielectric material of the diffusion structures 258 using a PVD technique, an ALD technique, a CVD technique, an oxidation technique, another deposition technique.

The recesses 302 are filled with the dielectric material to form the diffusion structures 258 prior to formation of recesses for the DTI structure 224 of the pixel sensor array 222, and prior to forming the metal insert 256 of the DTI structure 224. This prevents the metal material of the metal insert 256 from being deposited in the recesses 302, which would otherwise need to be removed from the recesses 302 by etching. Instead, the dielectric material is deposited such that the dielectric material of the diffusion structures 258 merge above the recesses 302 to form a continuous layer. A planarization tool may be used to planarize the top surface of the dielectric material such that the top surface of the dielectric material is substantially flat. This provide a flat substrate on which a metal fill layer may be formed, which enables the metal fill layer to be planarized to form the metal insert 256 of the DTI structure 224 as opposed to etching the metal fill layer.

As shown in FIG. 8D, recesses 806 for the DTI structure 224 may be formed around the photodiode 112 in the substrate 246 after formation of the diffusion structures 258. The recesses 806 may be formed from the second side 804 (e.g., the back side) of the substrate 246. The recesses 806 may also be formed through the dielectric material of the diffusion structures 258 as a result of the diffusion structures 258 being formed prior to formation of the recesses 806 for the DTI structure 224.

In some implementations, a pattern in a photoresist layer is used to etch the second side 804 of the substrate 246 to form the recesses 806. In these implementations, a deposition tool may be used to form the photoresist layer on the second side 804 of the substrate 246. An exposure tool may be used to expose the photoresist layer to a radiation source to pattern the photoresist layer. A developer tool may be used to develop and remove portions of the photoresist layer to expose the pattern. An etch tool may be used to etch into the substrate 246 from the second side 804 of the substrate based on the pattern to form the recesses 806. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate 246 based on a pattern.

As shown in FIG. 8E, the dielectric liner 254 of the DTI structure 224 is conformally deposited on the sidewalls and bottom surface of the recesses 806. A deposition tool may be used to deposit the dielectric liner 254 using a conformal deposition technique such as ALD. Additionally and/or alternatively, another deposition technique such as CVD may be used. The dielectric liner 254 may continuously extend over the second side 804 (e.g., the back side) of the substrate 246 such that the dielectric liner 254 is included over the photodiode 112 and over the diffusion structures 258.

As shown in FIG. 8F, the dielectric layer 252 of the DTI structure 224 may be formed on the dielectric liner 254 on the sidewalls and on the bottom surface of the recesses 806. the dielectric layer 252 may be formed such that open space still remains in the recesses 806 for formation of the metal insert 256. A deposition tool may be used to deposit the dielectric layer 252 using a PVD technique, an ALD technique, a CVD technique, an oxidation technique, another deposition technique. The dielectric layer 252 may continuously extend over the second side 804 (e.g., the back side) of the substrate 246 such that the dielectric layer 252 is included over the photodiode 112 and over the diffusion structures 258.

As shown in FIG. 8G, the remaining open space in the recesses 806 is filled with a metal fill layer 808. The metal fill layer 808 is deposited on the dielectric layer 252 in the recesses 806. The metal fill layer 808 may be deposited such that the metal fill layer 808 also extends across the photodiode 112 and merges over the photodiode 112 to formed a merged portion 810 of the metal fill layer 808. This ensures that the recesses 806 are fully filled in with the metal fill layer 808. A deposition tool may be used to deposit the metal fill layer 808 using a CVD technique, a PVD technique, an ALD technique, an electroplating technique, and/or another suitable deposition technique.

As shown in FIG. 8H, a planarization operation, such as a chemical mechanical planarization (CMP) operation, is performed using a planarization tool to planarize the metal fill layer 808 to remove the merged portion 810 of the metal fill layer 808 over the photodiode 112. The planarization of the metal fill layer 808 results in formation of the metal insert 256 of the DTI structure 224. The portions of the dielectric liner 254 and the dielectric layer 252 over the photodiode 112 may also be removed in the planarization operation, as shown in the example in FIG. 8H, to form one or more of the examples of pixel sensors 100 illustrated in FIGS. 3A-3D. Alternatively, the planarization operation may stop after removal of the merged portion 810 of the metal fill layer 808, and prior to removal of the portions of the dielectric liner 254 and the dielectric layer 252 over the photodiode 112, to form the example of the pixel sensor 100 illustrated in FIG. 3E.

As shown in FIG. 8I, the passivation layer 268 is formed over and/or on the dielectric material of the diffusion structures 258 and over and/or on the DTI structure 224. A deposition tool may be used to deposit the dielectric layer 252 using a PVD technique, an ALD technique, a CVD technique, an oxidation technique, another deposition technique. In some implementations, a planarization tool is used to planarize the passivation layer 268 after the passivation layer 268 is deposited.

As further shown in FIG. 8I, the metal grid structure 270 may be formed over and/or on the passivation layer 268. A deposition tool may be used to deposit a metal layer on the passivation layer 268 using a CVD technique, a PVD technique, an ALD technique, an electroplating technique, and/or another suitable deposition technique. The metal layer may be patterned using lithography techniques and etched to form the metal grid structure 270. The color filter region 272 may be formed in the metal grid structure 270, and the micro-lens 274 may be formed on the color filter region 272.

As indicated above, FIGS. 8A-8I are provided as an example. Other examples may differ from what is described with regard to FIGS. 8A-8I.

FIGS. 9A-9I are diagrams of an example implementation 900 of forming a pixel sensor array 222 of a sensor die 208 (or a portion thereof) described herein. In some implementations, one or more of the semiconductor processing operations described in connection with FIGS. 9A-9I may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 9A, an ion implantation tool may be used to implant dopants into the substrate 246 from a first side 802 of the substrate 246 (e.g., a front side of the substrate 246) to form the photodiode 112 of a pixel sensor 100 of the pixel sensor array 222.

As shown in FIGS. 9B-9I, back side processing may be performed after additional operations described in FIGS. 6C-6F, 7A, and/or 7B are performed. As shown in FIG. 9B, the recesses 302 for the diffusion structures 258 of the pixel sensor 100 may be formed in the second side 804 (e.g., the back side) of the substrate 246.

As shown in FIG. 9C, a doped layer 902 is formed on the sidewalls of the recesses 302. The doped layer 902 includes a polysilicon material and/or another type of material that is doped with one or more types of dopants (e.g., n-type dopants, p-type dopants). A deposition tool may conformally deposit the doped layer 902 using a conformal deposition technique such CVD or ALD. Additionally and/or alternatively, another deposition technique may be used to deposit the doped layer 902.

As shown in FIG. 9D, an annealing operation is performed to anneal the doped layer 902. The annealing operation (which is sometimes referred to as a dynamic surface anneal (DSA) operation) results in dopants from the doped layer 902 diffusing into the surface of the substrate 246, including the sidewalls of the recesses 302. The diffusion of dopants results in formation of the doped implant liner 402 in the substrate 246. Thus, the doped implant liner 402 is formed from the second side 804 of the substrate 246. The doped implant liner 402 passivates damage to the substrate 246 that may have occurred during formation of the recesses 302.

As shown in FIG. 9E, the doped layer 902 is subsequently removed after the annealing operation. The doped layer 902 may be removed by etching, ashing, and/or another suitable technique.

As shown in FIG. 9F, the recesses 302 are filled with dielectric material to form the diffusion structures 258 in the recesses 302 above the photodiode 112. In this way, the diffusion structures 258 are formed on the second side 804 (e.g., the back side) of the substrate 246 such that the diffusion structures 258 extend into the doped implant region 304. A deposition tool may be used to deposit the dielectric material of the diffusion structures 258 using a PVD technique, an ALD technique, a CVD technique, an oxidation technique, another deposition technique.

The recesses 302 are filled with the dielectric material to form the diffusion structures 258 prior to formation of recesses for the DTI structure 224 of the pixel sensor array 222, and prior to forming the metal insert 256 of the DTI structure 224. This prevents the metal material of the metal insert 256 from being deposited in the recesses 302, which would otherwise need to be removed from the recesses 302 by etching. Instead, the dielectric material is deposited such that the dielectric material of the diffusion structures 258 merge above the recesses 302 to form a continuous layer. A planarization tool may be used to planarize the top surface of the dielectric material such that the top surface of the dielectric material is substantially flat. This provide a flat substrate on which a metal fill layer may be formed, which enables the metal fill layer to be planarized to form the metal insert 256 of the DTI structure 224 as opposed to etching the metal fill layer.

As shown in FIGS. 9G and 9H, similar semiconductor processing operations as described in connection with FIGS. 8D-8H may be performed to form the DTI structure 224 may be formed around the photodiode 112 in the substrate 246 after formation of the diffusion structures 258. As shown in FIGS. 9G, the dielectric liner 254, the dielectric layer 252, and the metal fill layer 808 may be formed. As shown in FIG. 9H, a planarization operation, such as a CMP operation, is performed using a planarization tool to planarize the metal fill layer 808 to remove the merged portion 810 of the metal fill layer 808 over the photodiode 112. The planarization of the metal fill layer 808 results in formation of the metal insert 256 of the DTI structure 224. The portions of the dielectric liner 254 and the dielectric layer 252 over the photodiode 112 may also be removed in the planarization operation, as shown in the example in FIG. 9H, to form one or more of the examples of pixel sensors 100 illustrated in FIGS. 4A-4D. Alternatively, the planarization operation may stop after removal of the merged portion 810 of the metal fill layer 808, and prior to removal of the portions of the dielectric liner 254 and the dielectric layer 252 over the photodiode 112, to form the example of the pixel sensor 100 illustrated in FIG. 4E.

As shown in FIG. 9I, the passivation layer 268 is formed over and/or on the dielectric material of the diffusion structures 258 and over and/or on the DTI structure 224. A deposition tool may be used to deposit the dielectric layer 252 using a PVD technique, an ALD technique, a CVD technique, an oxidation technique, another deposition technique. In some implementations, a planarization tool is used to planarize the passivation layer 268 after the passivation layer 268 is deposited.

As further shown in FIG. 9I, the metal grid structure 270 may be formed over and/or on the passivation layer 268. A deposition tool may be used to deposit a metal layer on the passivation layer 268 using a CVD technique, a PVD technique, an ALD technique, an electroplating technique, and/or another suitable deposition technique. The metal layer may be patterned using lithography techniques and etched to form the metal grid structure 270. The color filter region 272 may be formed in the metal grid structure 270, and the micro-lens 274 may be formed on the color filter region 272.

As indicated above, FIGS. 9A-9I are provided as an example. Other examples may differ from what is described with regard to FIGS. 9A-9I.

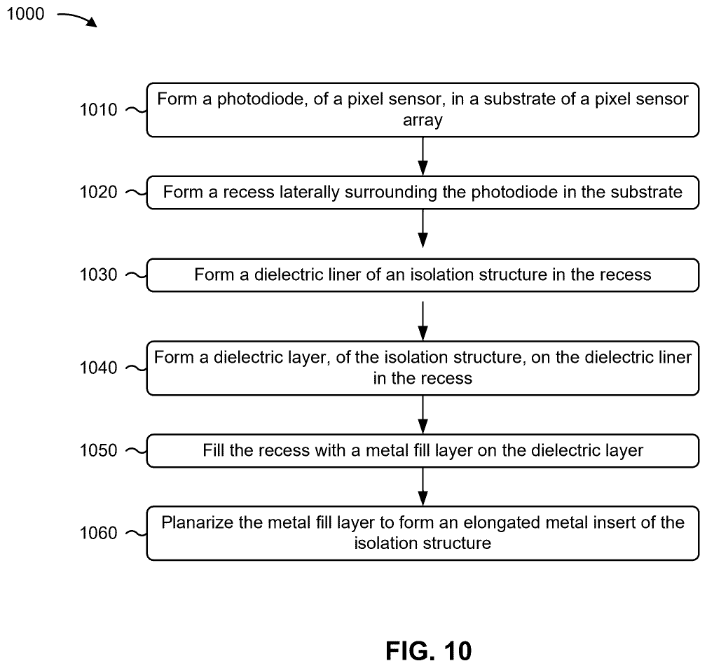

FIG. 10 is a flowchart of an example process 1000 associated with forming a pixel sensor array described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming a photodiode, of a pixel sensor, in a substrate of a pixel sensor array (block 1010). For example, one or more semiconductor processing tools may be used to form a photodiode 112 of a pixel sensor 100 in a substrate 246 of a pixel sensor array 222, as described herein.

As further shown in FIG. 10, process 1000 may include forming a recess laterally surrounding the photodiode in the substrate (block 1020). For example, one or more semiconductor processing tools may be used to form a recess 806 laterally surrounding the photodiode 112 in the substrate 246, as described herein.

As further shown in FIG. 10, process 1000 may include forming a dielectric liner of an isolation structure in the recess (block 1030). For example, one or more semiconductor processing tools may be used to form a dielectric liner 254 of an isolation structure (e.g., a DTI structure 224) in the recess 806, as described herein. In some implementations, one or more semiconductor processing tools may be used to form a dielectric liner 254 of an isolation structure (e.g., a DTI structure 224) on sidewalls and on a bottom surface of the recess 806.

As further shown in FIG. 10, process 1000 may include forming a dielectric layer of the isolation structure on the dielectric liner in the recess (block 1040). For example, one or more semiconductor processing tools may be used to form a dielectric layer 252 of the isolation structure on the dielectric liner in the recess, as described herein.

As further shown in FIG. 10, process 1000 may include filling the recess with a metal fill layer on the dielectric layer (block 1050). For example, one or more semiconductor processing tools may be used to fill the recess 806 with a metal fill layer 808 on the dielectric layer 252, as described herein.

As further shown in FIG. 10, process 1000 may include planarizing the metal fill layer to form an elongated metal insert of the isolation structure (block 1060). For example, one or more semiconductor processing tools may be used to planarize the metal fill layer 808 to form an elongated metal insert 256 of the isolation structure, as described herein.

Process 1000 may include additional implementations, such as any single implementation or any combination of implementations described below and/or in connection with one or more other processes described elsewhere herein.

In a first implementation, forming the dielectric liner 254 includes forming the dielectric liner 254 over the photodiode 112.

In a second implementation, alone or in combination with the first implementation, process 1000 includes planarizing the dielectric liner 254 to remove the dielectric liner 254 from over the photodiode 112.

In a third implementation, alone or in combination with one or more of the first and second implementations, filling the recess 806 with the metal fill layer 808 includes filling the recess 806 with the metal fill layer 808 such that the metal fill layer 808 merges to form a merged portion 810 above the photodiode 112, and planarizing the metal fill layer 808 to form the elongated metal insert 256 includes planarizing the metal fill layer 808 to remove the merged portion 810 above the photodiode 112 to form the elongated metal insert 256.

In a fourth implementation, alone or in combination with one or more of the first through third implementations, the elongated metal insert 256 includes copper (Cu).

In a fifth implementation, alone or in combination with one or more of the first through fourth implementations, the dielectric liner 254 includes a high-k dielectric material, and the dielectric layer 252 includes a low-k dielectric material.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

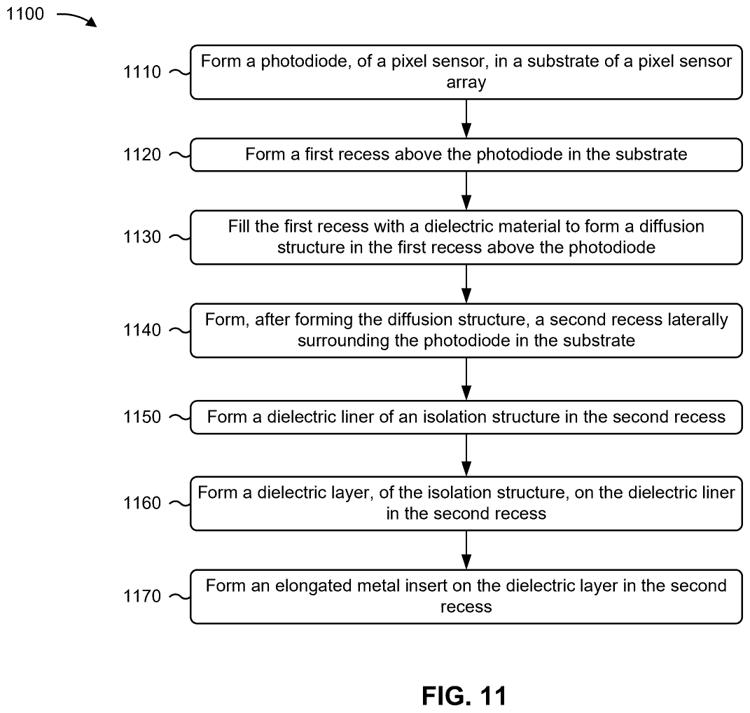

FIG. 11 is a flowchart of an example process 1100 associated with forming a pixel sensor array described herein. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include forming a photodiode, of a pixel sensor, in a substrate of a pixel sensor array (block 1110). For example, one or more semiconductor processing tools may be used to form a photodiode 112, of a pixel sensor 100, in a substrate 246 of a pixel sensor array 222, as described herein.

As further shown in FIG. 11, process 1100 may include forming a first recess above the photodiode in the substrate (block 1120). For example, one or more semiconductor processing tools may be used to form a first recess 302 above the photodiode 112 in the substrate 246, as described herein.

As further shown in FIG. 11, process 1100 may include filling the first recess with a dielectric material to form a diffusion structure in the first recess above the photodiode (block 1130). For example, one or more semiconductor processing tools may be used to fill the first recess 302 with a dielectric material to form a diffusion structure 258 in the first recess 302 above the photodiode 112, as described herein.

As further shown in FIG. 11, process 1100 may include forming, after forming the diffusion structure, a second recess laterally surrounding the photodiode in the substrate (block 1140). For example, one or more semiconductor processing tools may be used to form, after forming the diffusion structure 258, a second recess 806 laterally surrounding the photodiode 112 in the substrate 246, as described herein.

As further shown in FIG. 11, process 1100 may include forming a dielectric liner of an isolation structure in the second recess (block 1150). For example, one or more semiconductor processing tools may be used to form a dielectric liner 254 of an isolation structure (e.g., a DTI structure 224) in the second recess 806, as described herein. In some implementations, one or more semiconductor processing tools may be used to form a dielectric liner 254 of an isolation structure (e.g., a DTI structure 224) on sidewalls and on a bottom surface of the second recess 806.

As further shown in FIG. 11, process 1100 may include forming a dielectric layer, of the isolation structure, on the dielectric liner in the second recess (block 1160). For example, one or more semiconductor processing tools may be used to form a dielectric layer 252, of the isolation structure, on the dielectric liner 254 in the second recess 806, as described herein.

As further shown in FIG. 11, process 1100 may include forming an elongated metal insert on the dielectric layer in the second recess (block 1170). For example, one or more semiconductor processing tools may be used to form an elongated metal insert 256 on the dielectric layer 252 in the second recess 806, as described herein.

Process 1100 may include additional implementations, such as any single implementation or any combination of implementations described below and/or in connection with one or more other processes described elsewhere herein.

In a first implementation, forming the second recess 806 includes forming the second recess 806 around the diffusion structure 258.

In a second implementation, alone or in combination with the first implementation, process 1100 includes forming a doped implant region (e.g., a bulk doped implant region 304, a doped implant liner 402) in the substrate 246, where the doped implant region is vertically adjacent to the photodiode 112.

In a third implementation, alone or in combination with one or more of the first and second implementations, forming the doped implant region comprises forming the doped implant region prior to forming the first recess.

In a fourth implementation, alone or in combination with one or more of the first through third implementations, forming the doped implant region includes forming the doped implant region prior to formation of the photodiode 112.

In a fifth implementation, alone or in combination with one or more of the first through fourth implementations, forming the doped implant region includes forming the doped implant region from a first side of the substrate 246, and forming the second recess 806 around the photodiode 112 in the substrate 246 includes forming, from a second side of the substrate 246 vertically opposing the first side, the second recess 806 around the photodiode 112 in the substrate 246.

In a sixth implementation, alone or in combination with one or more of the first through fifth implementations, forming the doped implant region includes forming the doped implant region after formation of the photodiode 112 and after formation of the first recess 302.

In a seventh implementation, alone or in combination with one or more of the first through sixth implementations, forming the photodiode 112 includes forming the photodiode 112 from a first side of the substrate 246, and where forming the doped implant region includes forming the doped implant region from a second side of the substrate 246 vertically opposing the first side.

In an eighth implementation, alone or in combination with one or more of the first through seventh implementations, forming the dielectric liner 254 includes forming the dielectric liner 254 over the diffusion structure 258.

In a ninth implementation, alone or in combination with one or more of the first through eighth implementations, the dielectric liner 254 includes a high-k dielectric material, and wherein the dielectric layer 252 and the dielectric material of the diffusion structure 258 each include a low-k dielectric material.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a metal insert is formed in a DTI structure that laterally surrounds a photodiode of a pixel sensor, and the metal insert is formed in a manner in which a metal layer is formed and planarized to form the metal insert as opposed to etching the metal layer to form the metal insert. Recesses for diffusion structures are formed and then fully filled with a dielectric material as opposed to partially filling the recesses with a dielectric layer and then forming the metal layer on the dielectric layer. In this way, the diffusion structures have a substantially flat top surface on which the metal layer is then formed, which enables the metal layer to be planarized instead of etched to form the metal insert. Forming the metal insert after forming the diffusion structures prevents the materials of the metal insert from limiting the size and/or shape of the diffusions structure, which provides greater manufacturing flexibility when forming the diffusion structures. The greater flexibility in selecting the size and/or shape of the diffusion structures enables the diffusion structures to be formed to distribute incident light for specific optical wavelengths and/or for a broader range of optical bandwidths. This may increase the QE of the pixel sensor. Additionally and/or alternatively, forming the metal insert by planarization instead of etching enables metals that have a high reflectivity such as copper to be used for the metal insert. This may increase the reflectivity of the DTI structure, which may increase the optical isolation provided by the DTI structure. Moreover, fully filling the recesses with the dielectric material as opposed to partially filling the recesses with a dielectric layer and then fully filling the recesses after formation of the metal insert results in fewer semiconductor processing operations, which may reduce the cost, complexity, and/or time for manufacturing the pixel sensor.

As described in greater detail above, some implementations described herein provide a method. The method includes forming a photodiode, of a pixel sensor, in a substrate of a pixel sensor array. The method includes forming a recess laterally surrounding the photodiode in the substrate. The method includes forming a dielectric liner of an isolation structure in the recess. The method includes forming a dielectric layer, of the isolation structure, on the dielectric liner in the recess. The method includes filling the recess with a metal fill layer on the dielectric layer. The method includes planarizing the metal fill layer to form an elongated metal insert of the isolation structure.

As described in greater detail above, some implementations described herein provide a method. The method includes forming a photodiode, of a pixel sensor, in a substrate of a pixel sensor array. The method includes forming a first recess above the photodiode in the substrate. The method includes filling the first recess with a dielectric material to form a diffusion structure in the first recess above the photodiode. The method includes forming, after forming the diffusion structure, a second recess laterally surrounding the photodiode in the substrate. The method includes forming a dielectric liner of an isolation structure in the second recess. The method includes forming a dielectric layer, of the isolation structure, on the dielectric liner in the second recess. The method includes forming an elongated metal insert on the dielectric layer in the second recess.

As described in greater detail above, some implementations described herein provide a pixel sensor array. The pixel sensor array includes a pixel sensor that includes a photodiode in a substrate. The pixel sensor array includes a DTI structure, laterally surrounding the photodiode in the substrate, that includes a conformal liner, a dielectric layer on the conformal liner, and an elongated metal insert in the dielectric layer. The pixel sensor array includes a diffusion structure in a recess in the substrate, where the diffusion structure is above the photodiode and within an inner perimeter of the DTI structure. The pixel sensor array includes a doped implant region in the substrate, where the doped implant region is between the photodiode and the diffusion structure.

The terms “approximately” and “substantially” can indicate a value of a given quantity that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a photodiode, of a pixel sensor, in a substrate of a pixel sensor array;
forming a recess laterally surrounding the photodiode in the substrate;
forming a dielectric liner of an isolation structure in the recess;
forming a dielectric layer, of the isolation structure, on the dielectric liner in the recess;
filling the recess with a metal fill layer on the dielectric layer; and
planarizing the metal fill layer to form an elongated metal insert of the isolation structure.

2. The method of claim 1, wherein forming the dielectric liner comprises:
forming the dielectric liner over the photodiode.

3. The method of claim 2, further comprising:
planarizing the dielectric liner to remove the dielectric layer from over the photodiode.

4. The method of claim 1, wherein filling the recess with the metal fill layer comprises:
filling the recess with the metal fill layer such that the metal fill layer merges to form a merged portion above the photodiode; and
wherein planarizing the metal fill layer to form the elongated metal insert comprises:
planarizing the metal fill layer to remove the merged portion above the photodiode to form the elongated metal insert.

5. The method of claim 1, wherein the elongated metal insert comprises copper (Cu).

6. The method of claim 1, wherein the dielectric liner comprises a high dielectric constant (high-k) dielectric material; and
wherein the dielectric layer comprises a low dielectric constant (low-k) dielectric material.

7. A method, comprising:
forming a photodiode, of a pixel sensor, in a substrate of a pixel sensor array;
forming a first recess above the photodiode in the substrate;
filling the first recess with a dielectric material to form a diffusion structure in the first recess above the photodiode;
forming, after forming the diffusion structure, a second recess laterally surrounding the photodiode in the substrate;
forming a dielectric liner of an isolation structure in the second recess;
forming a dielectric layer, of the isolation structure, on the dielectric liner in the second recess; and
forming an elongated metal insert on the dielectric layer in the second recess.

8. The method of claim 7, wherein forming the second recess comprises:
forming the second recess around the diffusion structure.

9. The method of claim 7, further comprising:
forming a doped implant region in the substrate,
wherein the doped implant region is vertically adjacent to the photodiode.

10. The method of claim 9, wherein forming the doped implant region comprises:
forming the doped implant region prior to forming the first recess.

11. The method of claim 9, wherein forming the doped implant region comprises:
forming the doped implant region prior to formation of the photodiode.

12. The method of claim 11, wherein forming the doped implant region comprises:
forming the doped implant region from a first side of the substrate; and
wherein forming the second recess around the photodiode in the substrate comprises:
forming, from a second side of the substrate vertically opposing the first side, the second recess around the photodiode in the substrate.

13. The method of claim 9, wherein forming the doped implant region comprises:
forming the doped implant region after formation of the photodiode and after formation of the first recess.

14. The method of claim 13, wherein forming the photodiode comprises:
forming the photodiode from a first side of the substrate; and
wherein forming the doped implant region comprises:
forming the doped implant region from a second side of the substrate vertically opposing the first side.

15. The method of claim 7, wherein forming the dielectric liner comprises:
forming the dielectric liner over the diffusion structure.

16. The method of claim 7, wherein the dielectric liner comprises a high dielectric constant (high-k) dielectric material; and
wherein the dielectric layer and the dielectric material of the diffusion structure each comprise a low dielectric constant (low-k) dielectric material.

17. A pixel sensor device, comprising:
a photodiode in a substrate;
a deep trench isolation (DTI) structure, laterally surrounding the photodiode in the substrate, comprising:
a conformal liner;
a dielectric layer over the conformal liner; and
an elongated metal insert in the dielectric layer;
a diffusion structure in a recess in the substrate,
wherein the diffusion structure is above the photodiode and within an inner perimeter of the DTI structure; and
a doped implant region in the substrate,
wherein the doped implant region is between the photodiode and the diffusion structure.

18. The pixel sensor array of claim 17, wherein the doped implant region comprises a blanket implant region extending between opposing sides of the inner perimeter of the DTI structure in a cross-section view of the pixel sensor array; and
wherein the blanket implant region extends between a top and a bottom of the recess in the substrate in which the diffusion structure is located.

19. The pixel sensor array of claim 17, wherein the doped implant region comprises a conformal implant region extending between opposing sides of the inner perimeter of the DTI structure in a cross-section view of the pixel sensor array; and
wherein the conformal implant region conforms to a cross-sectional profile of the recess in the substrate in which the diffusion structure is located.

20. The pixel sensor array of claim 17, wherein the diffusion structure is in direct physical contact with the substrate in the recess; and
wherein the conformal liner extends above and over the diffusion structure.
